(19) United States
(12) Patent Application Publication
(10) Pub. No.: US 2026/0354156 A1
(43) Pub. Date: Nov. 5, 2026

(54) METAL OR POLYMER LAYERS TO PROTECT SEMICONDUCTOR PACKAGE BOND PADS FROM CONTAMINATION

(71) Applicant: TEXAS INSTRUMENTS INCORPORATED, Dallas, TX (US)

(72) Inventors: Kashyap MOHAN, McKinney, TX (US); Zhaoqiang LI, Wuxi (CN)

(21) Appl. No.: 19/195,595

(22) Filed: Apr. 30, 2025

(51) Int. Cl. H10W 20/43; H05K 1/181; H10P 50/00; H10W 20/44; H10W 20/48; H10W 72/00; H10W 72/50; H10W 74/01; H10W 90/00

(52) U.S. Cl. CPC H10W 20/43; H10P 50/691; H10W 20/4403; H10W 20/48; H10W 74/016; H10W 90/00; H05K 1/181; H10W 72/0198; H10W 72/536; H10W 72/5363; H10W 72/865; H10W 72/884; H10W 90/736; H10W 90/738; H10W 90/756; H10W 90/758

(57) ABSTRACT

In examples, a semiconductor package includes a bulk acoustic wave (BAW) resonator die having a device side in which circuitry is formed, a support structure coupled to the device side and circumscribing the circuitry, a bond pad coupled to the device side and outside a perimeter of the support structure, a metal or polymer layer coupled to the support structure and covering the circuitry, an etch stop layer coupled to the metal or polymer layer, and a passive semiconductor structure coupled to the etch stop layer such that the etch stop layer is between the semiconductor structure and the metal or polymer layer. The outer lateral surfaces of the metal or polymer layer, the etch stop layer, and the semiconductor structure are approximately flush with each other, and an entirety of the outer lateral surfaces of the semiconductor structure have plasma-etch striations.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die may then be coupled to a substrate or die pad. The resulting structure is subsequently covered with a mold compound to produce a package.

### SUMMARY

In examples, a semiconductor package includes a bulk acoustic wave (BAW) resonator die having a device side in which circuitry is formed, a support structure coupled to the device side and circumscribing the circuitry, a bond pad coupled to the device side and outside a perimeter of the support structure, a metal or polymer layer coupled to the support structure and covering the circuitry, an etch stop layer coupled to the metal or polymer layer, and a passive semiconductor structure coupled to the etch stop layer such that the etch stop layer is between the semiconductor structure and the metal or polymer layer. The outer lateral surfaces of the metal or polymer layer, the etch stop layer, and the semiconductor structure are approximately flush with each other, and an entirety of the outer lateral surfaces of the semiconductor structure have plasma-etch striations.

In examples, a method for manufacturing a semiconductor package includes coupling an oxide layer having a semiconductor structure coupled thereto to a support structure on a device side of a semiconductor wafer, the semiconductor wafer having circuitry formed in the device side, the support structure circumscribing the circuitry, the semiconductor wafer having a bond pad outside of a perimeter of the support structure; patterning a photoresist layer on the semiconductor structure; etching the semiconductor structure using the photoresist layer to form a cavity above the bond pad, a portion of the semiconductor structure between the cavity and the oxide layer having a thickness; removing the portion of the semiconductor structure and a portion of the oxide layer below the portion of the semiconductor structure using a water jet; sawing through the semiconductor wafer to produce a singulated semiconductor die; coupling a bond wire to the bond pad; and applying a mold compound to the semiconductor die, the semiconductor structure, the bond pad, and the bond wire.

### BRIEF DESCRIPTION OF THE DRAWINGS

FIG. 1 is a flow diagram of a method for manufacturing a semiconductor package using a metal or polymer layer to protect bond pads from contamination, in accordance with various examples.

FIG. 2A1, 2A2, 2B1, 2B2, 2C1, 2C2, 2D1, 2D2, 2E1, 2E2, 2F1, 2F2, 2G1, 2G2, 2H1, 2H2, 2I1, 2I2, 3A, 3B, and 3C are a process flow for a method of manufacturing a semiconductor package using a metal or polymer layer to protect bond pads from contamination, in accordance with various examples.

FIG. 4A1, 4A2, 4B1, 4B2, 4C1, 4C2, 4D1, 4D2, 4E1, 4E2, 4F1, 4F2, 4G1, 4G2, 4H1, 4H2, 4I1, 4I2, 5A, 5B, and 5C are a process flow for a method of manufacturing a semiconductor package using a metal or polymer layer to protect bond pads from contamination, in accordance with various examples.

FIG. 6 is a flow diagram of a method for manufacturing a semiconductor package using a selective etching and water jet technique to protect bond pads from contamination, in accordance with various examples.

FIG. 7A1, 7A2, 7B1, 7B2, 7C1, 7C2, 7D1, 7D2, 7E1, 7E2, 7F1, 7F2, 7G1, 7G2, 7H1, 7H2, 7I1, 7I2, 8A, 8B, and 8C are a process flow for a method of manufacturing a semiconductor package using a selective etching and water jet technique to protect bond pads from contamination, in accordance with various examples.

FIG. 9 is a block diagram of an example electronic device including a semiconductor package manufactured according to any of the techniques described herein.

### DETAILED DESCRIPTION

Certain wafer-level manufacturing techniques, for example in the bulk acoustic wave (BAW) and microelectromechanical systems (MEMS) contexts, entail plasma etching through silicon to expose bond pads to which bond wires are subsequently coupled. In such cases, the silicon is directly above the bond pads, and thus etching through the silicon directly above the bond pads exposes the bond pads to debris that can damage and/or contaminate the bond pads. To mitigate the risk of such damage or contamination, an etch stop layer is coupled to the bottom surface of the silicon to prevent etching beyond the silicon. Further, the etch stop layer prevents debris from falling directly onto the bond pads. However, such etch stop layers frequently form cracks through which etching gases (e.g., plasma etch gases) can pass, accumulating on or near the bond pads and causing contaminants to form on the bond pads. Thus, etch stop layers inadequately protect the bond pads.

This description presents various examples of semiconductor packages and semiconductor package manufacturing techniques in which bond pads are adequately protected from the damage and contamination described above, such as those associated with semiconductor etching processes. More specifically, a metal or polymer layer is coupled to the etch stop layer such that the etch stop layer is between the metal or polymer layer and the silicon. The metal or polymer layer prevents the flow of gases toward the bond pad even in the presence of cracks in the etch stop layer, thereby preventing the formation of contaminants on the bond pads and preventing debris from damaging the bond pads. In examples, a semiconductor package manufacturing method includes coupling an oxide layer having a semiconductor structure coupled thereto to a support structure on a device side of a semiconductor wafer. The semiconductor wafer has circuitry formed in the device side. The support structure circumscribes the circuitry, and the semiconductor wafer has a bond pad outside of a perimeter of the support structure. The method also includes patterning a photoresist layer on the semiconductor structure and etching the semiconductor structure using the photoresist layer to form a cavity above the bond pad. A portion of the semiconductor structure between the cavity and the oxide layer has a thickness. The method further comprises removing the portion of the semiconductor structure and a portion of the oxide layer below the portion of the semiconductor structure using a water jet. The method includes sawing through the semiconductor wafer to produce a singulated semiconductor die and coupling a bond wire to the bond pad. The method also includes applying a mold compound to the semiconductor die, the semiconductor structure, the bond pad, and the bond wire.

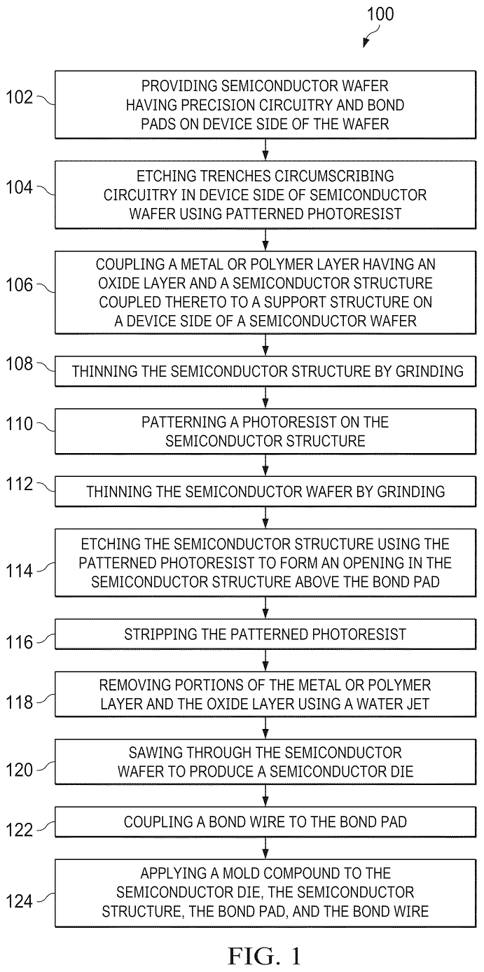

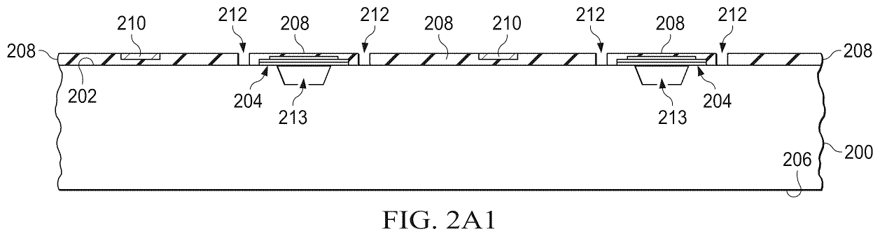

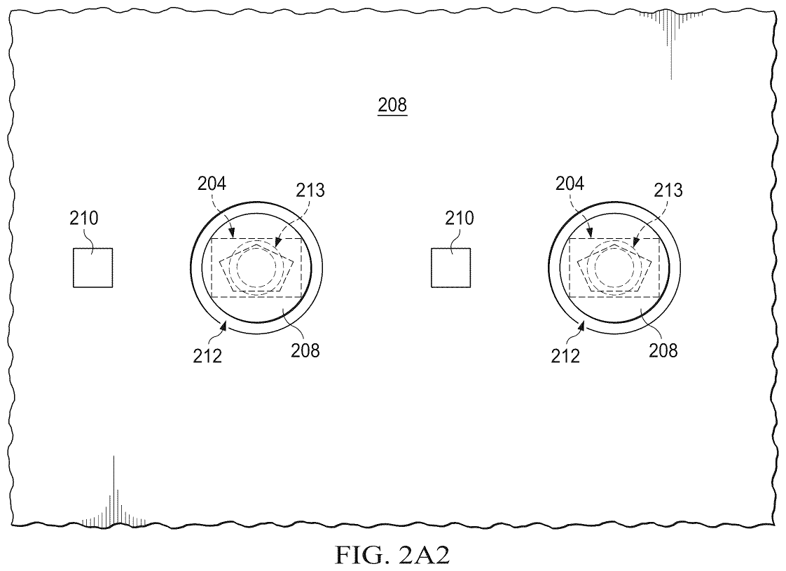

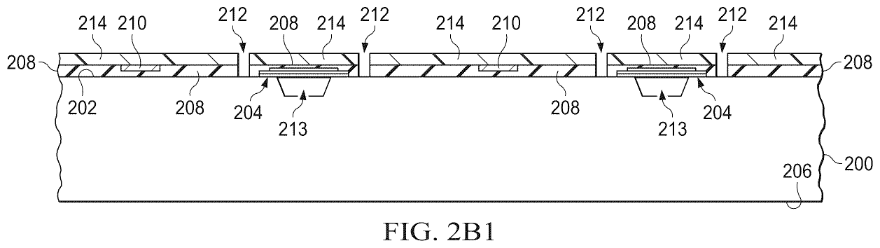

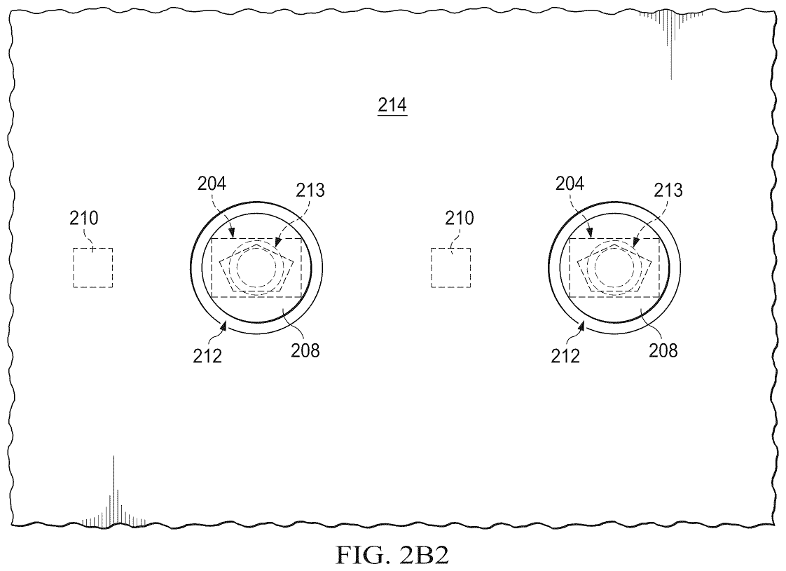

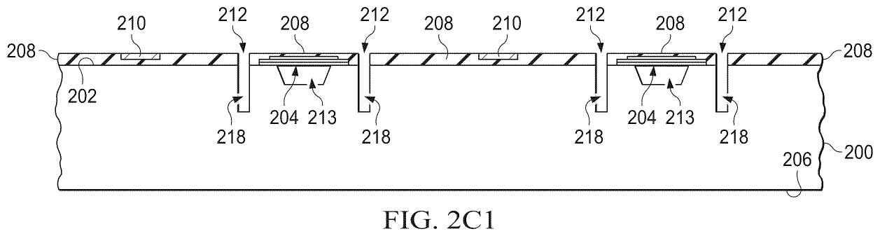

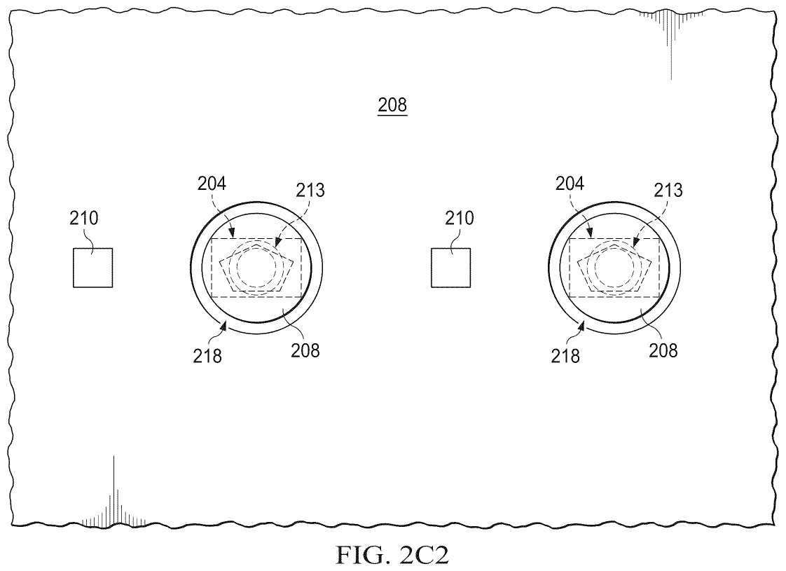

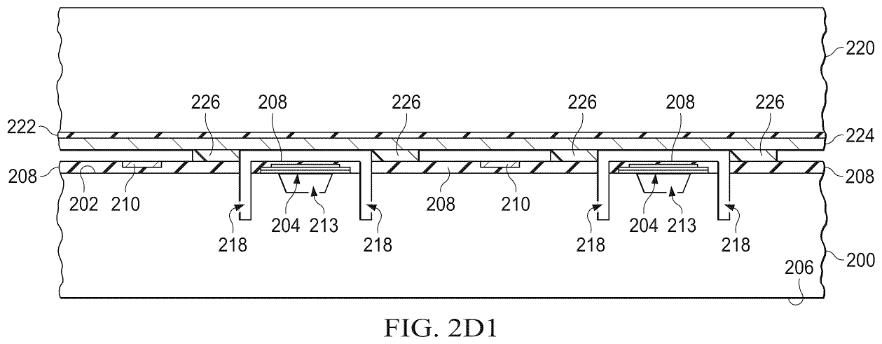

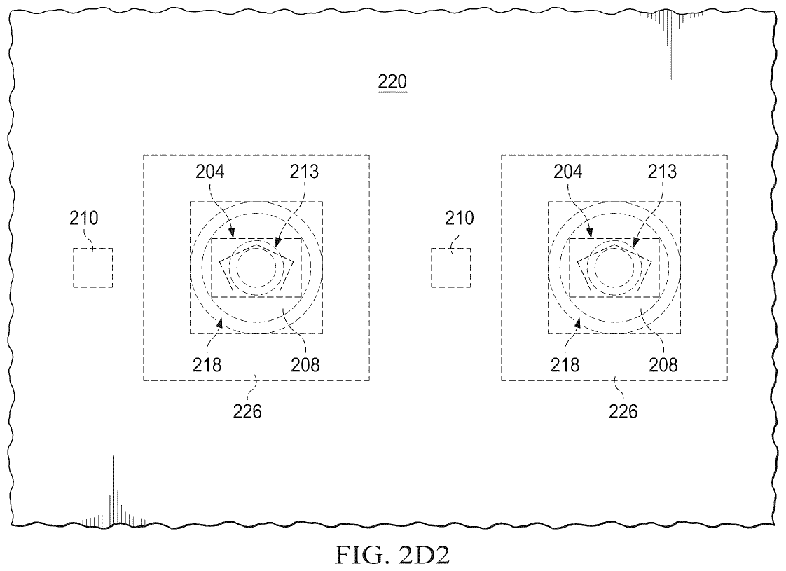

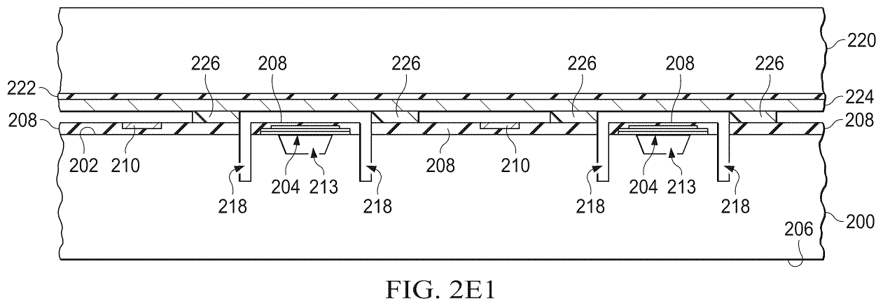

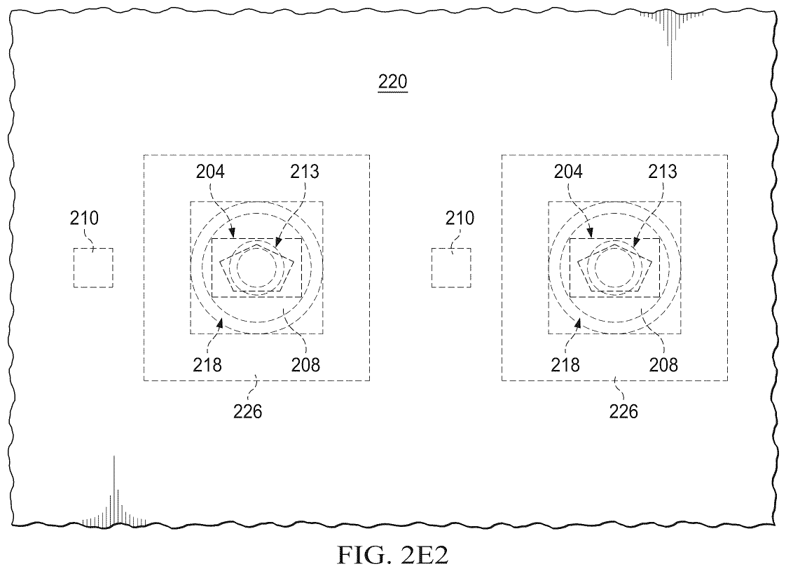

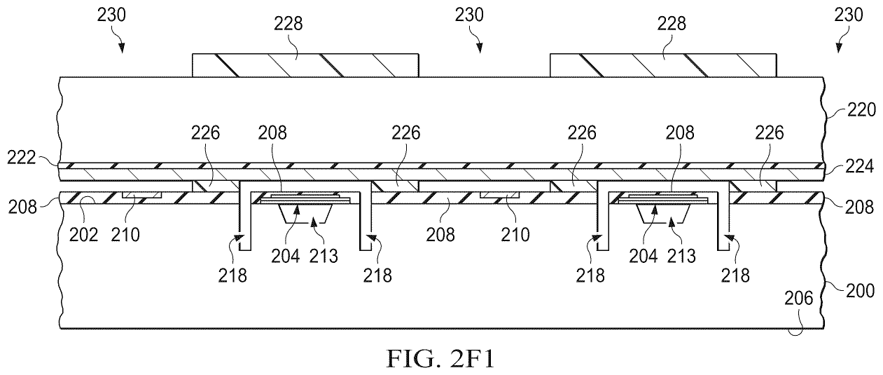

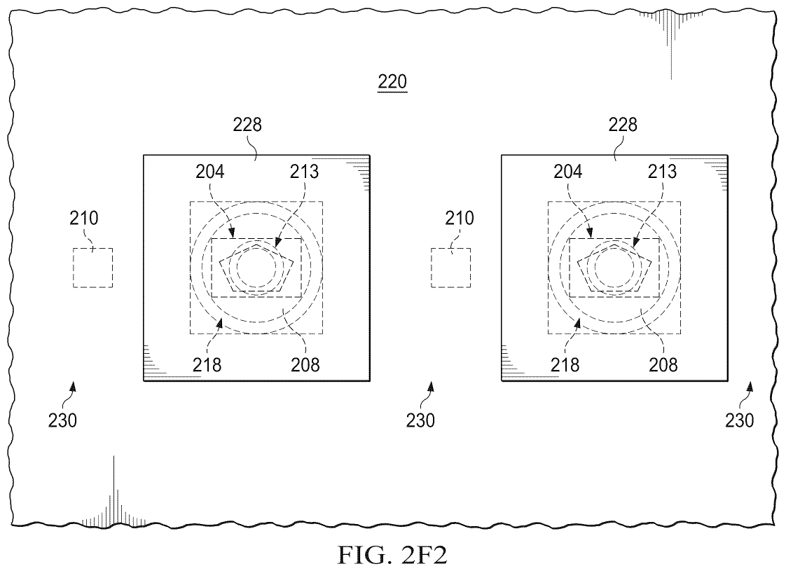

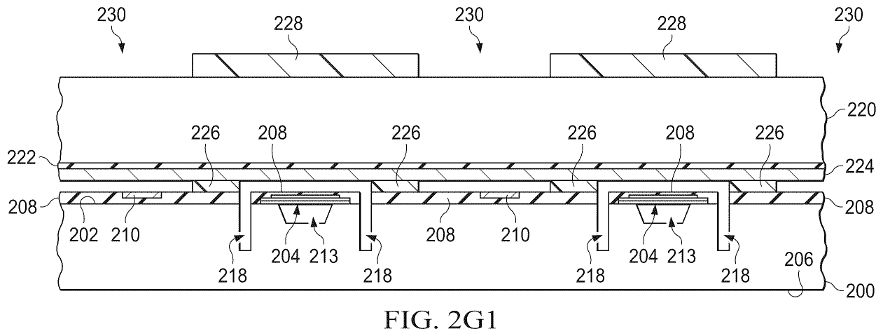

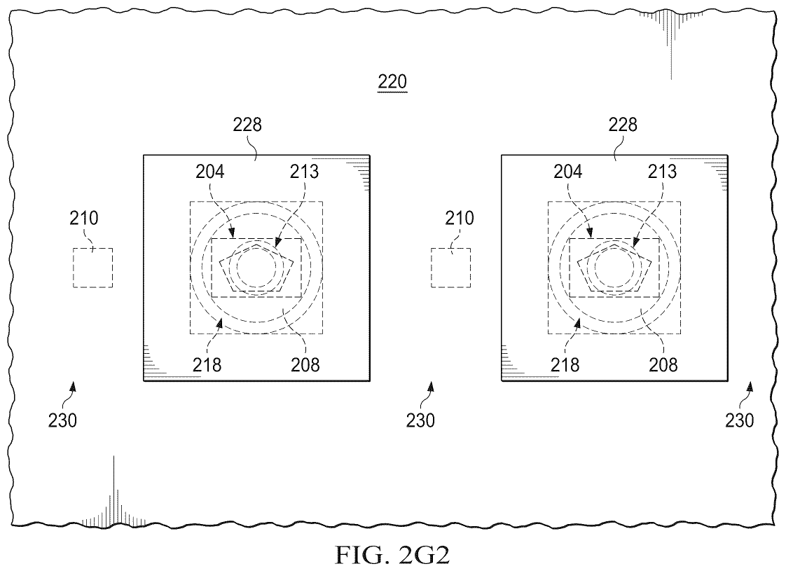

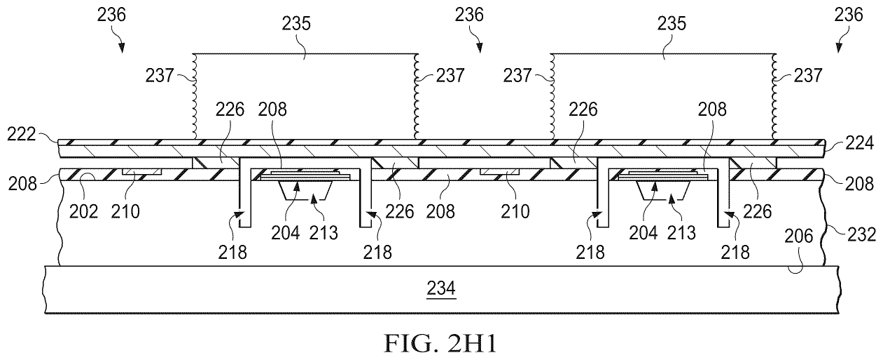

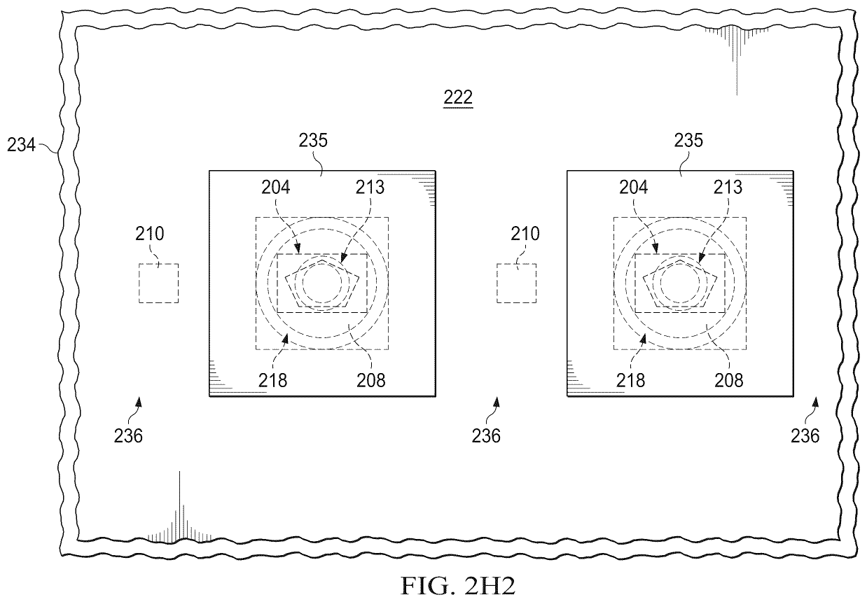

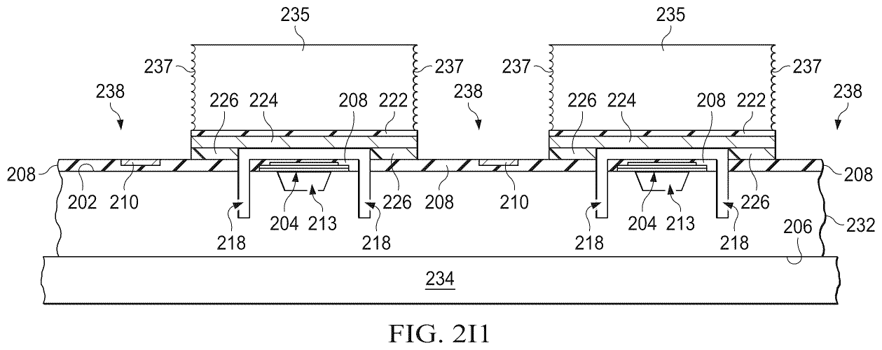

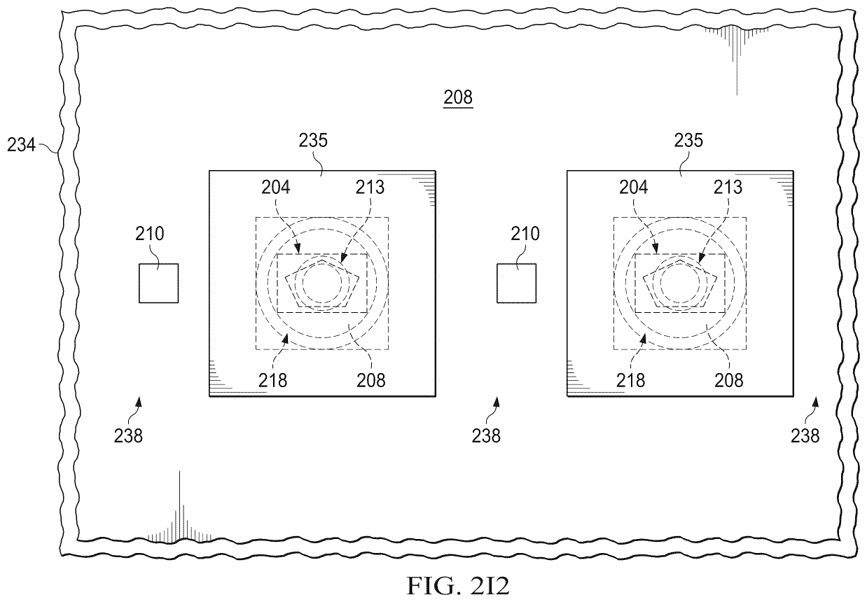

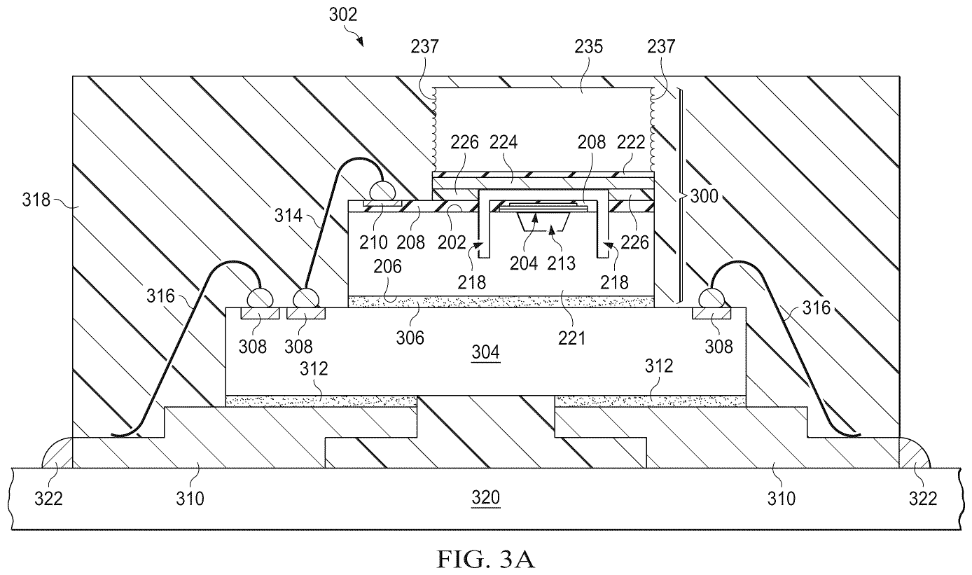

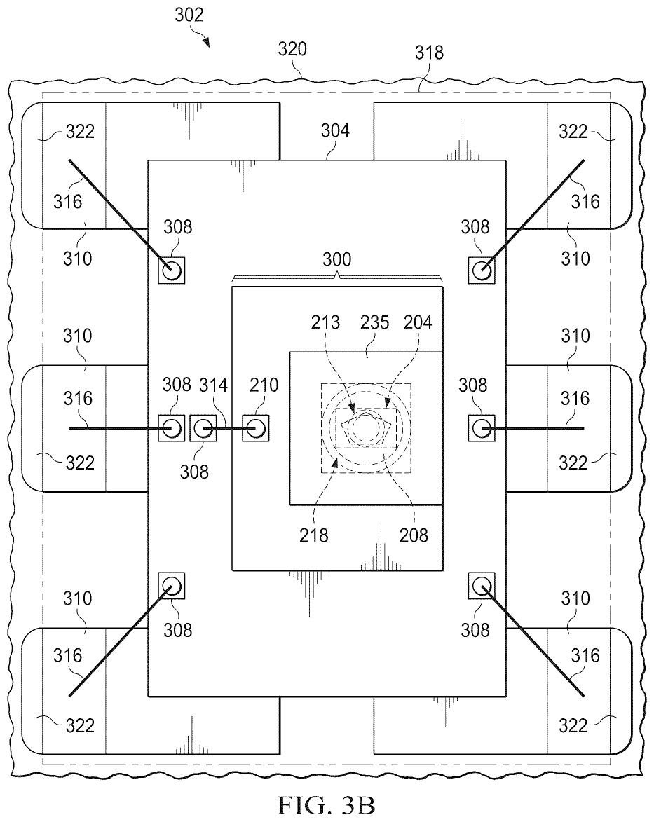

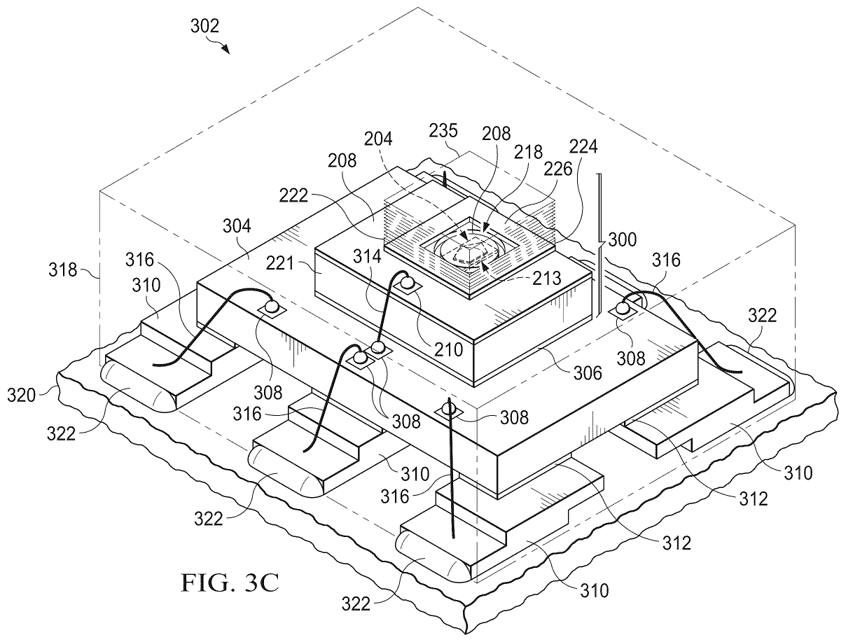

FIG. 1 is a flow diagram of a method 100 for manufacturing a semiconductor package using a metal or polymer layer to protect bond pads from contamination, in accordance with various examples. FIG. 2A1, 2A2, 2B1, 2B2, 2C1, 2C2, 2D1, 2D2, 2E1, 2E2, 2F1, 2F2, 2G1, 2G2, 2H1, 2H2, 2I1, 2I2, 3A, 3B, and 3C are a process flow for a method of manufacturing a semiconductor package using a metal or polymer layer to protect bond pads from contamination, in accordance with various examples. Accordingly, FIGS. 1 and 2A1-3C are now described in parallel.

The method 100 includes providing a semiconductor wafer having precision circuitry and bond pads on a device side of the wafer (102). FIG. 2A1 and 2A2 are profile cross-sectional and top-down views of a semiconductor wafer 200 (e.g., silicon, gallium nitride) having a device side 202 in and/or on which precision circuitry 204 is formed, and a non-device side 206 opposite the device side 202. No circuitry is formed in the non-device side 206. A passivation layer 208 physically contacts the device side 202 of the semiconductor wafer 200. Bond pads 210 are exposed on a top surface of the passivation layer 208 that faces away from the device side 202. The bond pads 210 are coupled to circuitry in and/or on the device side 202 through vias and/or one or more additional metal layers, which are not expressly shown for the sake of clarity. The passivation layer 208 includes multiple trenches 212, which are in a grid pattern when viewed in a top-down view. Precision circuitry 204 is present between consecutive pairs of trenches 212, and bond pads 210 are present between consecutive pairs of trenches 212, as shown. The precision circuitry 204 is any suitable type of circuitry. In examples, the semiconductor wafer 200 is a bulk acoustic wave (BAW) resonator wafer and the precision circuitry 204 is a resonator element. In examples, an air cavity 213 is present below each instance of the precision circuitry 204. The air cavity 213 facilitates directional operation of the precision circuitry 204 (e.g., when the precision circuitry 204 is a resonator element) and/or provides mechanical stress isolation to the precision circuitry 204 to improve operation. Although the precision circuitry 204 is generally described herein as being high-precision, in examples, the precision circuitry 204 is non-precision circuitry.

The method 100 includes etching trenches circumscribing circuitry in the device side of the semiconductor wafer using a patterned photoresist (104). FIG. 2B1 and 2B2 are profile cross-sectional and top-down views of the structure of FIG. 2A1 and 2A2, except that a patterned photoresist 214 is applied to the top surface of the passivation layer 208. The patterned photoresist 214 is patterned, for example, using a suitable photolithography technique, such as with a patterned mask, light exposure, and chemical solvents for development of the exposed areas of the photoresist to produce the patterned photoresist 214. The patterned photoresist 214 is patterned such that the trenches 212 are exposed through the patterned photoresist 214, while the remainder of the passivation layer 208 is covered, as shown. FIG. 2C1 and 2C2 are profile cross-sectional and top-down views of the structure of FIG. 2B1 and 2B2, except that trenches 218 are etched into the device side 202 of the semiconductor wafer 200 using the patterned photoresist 214. Each of the trenches 218 is vertically aligned with a respective trench 212, and thus each trench 218 and the respective trench 212 may be considered as a single trench 216/218, with the numeral 216 denoting the portion of the trench that is coplanar with the passivation layer 208, and the numeral 218 denoting the portion of the trench that is within the semiconductor wafer 200. The trench 216/218 circumscribes the precision circuitry 204. The trench 218 extends between 20 microns and approximately half the thickness of the semiconductor wafer 200 deep into the semiconductor wafer 200 as measured from the device side 202, with a depth below this range being disadvantageous because a lower depth does not adequately isolate the mechanical stress, and with a depth above this range being disadvantageous because of the significant risk of wafer cracking.

The method 100 includes coupling a metal or polymer layer having an oxide layer and a semiconductor structure coupled thereto to a support structure on the device side of the semiconductor wafer (106). FIG. 2D1 and 2D2 are profile cross-sectional and top-down views of the structure of FIG. 2C1 and 2C2, except that a semiconductor structure 220, a metal or polymer layer 224, and an oxide layer 222 in between the semiconductor structure 220 and the metal or polymer layer 224 is coupled to a support structure 226 on the device side 202, and more specifically, on the passivation layer 208. The semiconductor structure 220 is passive, meaning that it lacks circuitry. All oxide layers (e.g., oxide layer 222) described herein may also be referred to as etch stop layers. The oxide layer 222 has a first side physically contacting the semiconductor structure 220 and a second side opposite the first side that physically contacts the metal or polymer layer 224. The metal or polymer layer 224 physically contacts the support structure 226. The support structure 226 circumscribes the trench 216/218 and the precision circuitry 204. The oxide layer 222 may be any suitable type of oxide layer, such as silicon dioxide. The metal or polymer layer 224 may be any suitable type of metal or polymer layer, such as aluminum, copper, tungsten, titanium-tungsten, polyimide, benzocyclobutene, polydimethylsiloxane, SU-8, and polybenzoxazoles. The support structure 226 may be any suitable type of rigid material, such as a polymer or copper/tin-silver or gold. The oxide layer 222 has a thickness ranging from 0.1 microns to 3 microns, with a thickness below this range being disadvantageous because it risks the oxide layer 222 being fully etched out, and with a thickness above this range being disadvantageous because of the risk that targeted portions of the oxide layer 222 become very challenging to remove during subsequent processes. The metal or polymer layer 224 has a thickness ranging from 0.05 microns to 5 microns, with a thickness below this range being disadvantageous because of the risk of cracking or breaking, and with a thickness above this range being disadvantageous because of the risk that targeted portions of the metal or polymer layer 222 become very challenging to remove during subsequent processes. The support structure 226 has a thickness ranging from 5 microns to 40 microns, with a thickness below this range being disadvantageous because of the risk of poor bond performance, and with a thickness above this range being disadvantageous because of the significantly increased risk of poor bond uniformity.

The method 100 includes thinning the semiconductor structure by grinding (108). FIG. 2E1 and 2E2 are profile cross-sectional and top-down views of the structure of FIG. 2D1 and 2D2, except that the semiconductor structure 220 has been thinned by grinding. For example, suitable back grinding techniques may be useful. The resulting thickness of the semiconductor structure 220 ranges from 50 microns to 300 microns, with a thickness below this range being disadvantageous because of the risk that the semiconductor wafer may be cracked or broken during cap grinding (i.e., if the grinding process continues beyond 50 microns thickness), and with a thickness above this range being disadvantageous because of an unacceptable increase in package thickness.

The method 100 includes patterning a photoresist on the semiconductor structure (110). FIG. 2F1 and 2F2 are profile cross-sectional and top-down views of the structure of FIG. 2E1 and 2E2, except that a patterned photoresist 228 is applied on a top side of the semiconductor structure 220 that faces away from the semiconductor wafer 200. The patterned photoresist 228 may be patterned using the photolithography techniques described above. The patterned photoresist 228 includes openings 230. The openings 230 are vertically aligned with respective gaps between consecutive support structures 226. For example, a vertical line may extend through both an opening 230 and a respective gap between consecutive support structures 226.

The method 100 includes thinning the semiconductor wafer by grinding (112). FIG. 2G1 and 2G2 are profile cross-sectional and top-down views of the structure of FIG. 2F1 and 2F2, except that the non-device side 206 of the semiconductor wafer 200 has been grinded to thin the semiconductor wafer 200, as numeral 232 indicates. The semiconductor wafer 200 is not grinded so much that the trenches 218 are reached and the semiconductor wafer 200 is singulated. Rather, the grinding should leave a thickness of the semiconductor wafer 200 between the non-device side 206 and the deepest points of the trenches 218 ranging from 30 microns and 300 microns, with a thickness below this range being disadvantageous because of the risk of cracking or breaking the semiconductor wafer 200, and with a thickness above this range being disadvantageous because it significantly increases package thickness.

The method 100 includes etching the semiconductor structure using the patterned photoresist to form an opening in the semiconductor structure above the bond pad (114). The method 100 includes stripping the patterned photoresist (116). FIG. 2H1 and 2H2 are profile cross-sectional and top-down views of the structure of FIG. 2G1 and 2G2, except that the structure of FIG. 2G1 and 2G2 is coupled to a carrier or tape 234, and the semiconductor structure 220 is etched (e.g., plasma etched) using the patterned photoresist 228, resulting in the openings 236 that singulate the semiconductor structure 220 into separate semiconductor structures 235, which are passive structures (i.e., lacking circuitry). The openings 236 extend through an entire thickness of the semiconductor structure 220, as shown. The patterned photoresist 228 is subsequently stripped away. The width of each opening 236 is approximately equal to the width of the gap between a respective pair of consecutive support structures 226, as shown. When the semiconductor structure 220 is plasma etched, plasma-etch striations 237 are formed on the walls of the opening 236. The striations 237 are present on all four lateral sides of each semiconductor structure 235. The striations 237 cover an entirety of each of the four lateral sides of each semiconductor structure 235. Each striation 237 is horizontally coplanar with a respective striation 237 on each of the remaining three sides of the semiconductor structure 235, because the plasma etching process is performed on the semiconductor structure 220 as a whole and thus the various openings 236 are formed simultaneously. Stated another way, each striation 237 extends across all four lateral surfaces of the respective semiconductor structure 235. Plasma-etch striations are microscale, parallel, scallop-like grooves and ridges formed on a material surface as a result of directional ion bombardment during plasma etching.

The etching process to create the openings 236 can damage the oxide layer 222. For example, cracks may form in the oxide layer 222. Further, gases used during the etching process, for example during plasma etching, can seep through these cracks in the oxide layer 222, eventually causing contaminants to form on the bond pads 210. It is also possible for debris associated with the oxide layer 222 to fall on the bond pads 210. The metal or polymer layer 224 blocks any gases that seep through the cracks in the oxide layer 222 from reaching the bond pads 210, thereby preventing the formation of contaminants on the bond pads 210. Similarly, the metal or polymer layer 224 blocks any debris from the oxide layer 222 from falling on the bond pads 210. Thus, the metal or polymer layer 224 preserves the structural and operational integrity of the bond pads 210 during the etching process. After the etching process is complete, the method 100 includes removing portions of the metal or polymer layer and the oxide layer using a water jet (118). FIG. 2I1 and 2I2 are profile cross-sectional and top-down views of the structure of FIG. 2H1 and 2H2, except that the portions of the oxide layer 222 and the metal or polymer layer 224 that vertically overlapped with the openings 236 are removed as numeral 238 indicates, such as by water jet.

The method 100 includes sawing through the semiconductor wafer to produce a semiconductor die (120), coupling a bond wire to the bond pad (122), and applying a mold compound to the semiconductor die, the semiconductor structure, the bond pad, and the bond wire (124). FIGS. 3A, 3B, and 3C are profile cross-sectional, top-down, and perspective views of the structure of FIG. 2I1 and 2I2, except that the structure of FIG. 2I1 and 2I2 has been singulated (e.g., sawn) to produce singulated structures 300 that are included inside a semiconductor package 302. More specifically, the singulated structure 300 is coupled to a semiconductor die 304 by a die attach layer 306. The semiconductor die 304 includes a device side physically contacting the die attach layer 306, in which circuitry is formed. The semiconductor die 304 includes a non-device side opposite the device side. The semiconductor die 304 includes circuitry in the device side that is configured to operate the circuitry in the singulated structure 300, such as the precision circuitry 204. The semiconductor die 304 includes bond pads 308. The semiconductor die 304 is coupled to conductive terminals 310 by die attach layers 312. The bond pads 210 are coupled to the bond pads 308 by the bond wires 314. Bond wires 316 couple the bond pads 308 to the conductive terminals 310. In examples, outer lateral surfaces of the semiconductor structure 235 share a vertical plane (i.e., are approximately flush) with respective outer lateral surfaces of the oxide layer 222 and respective outer lateral surfaces of the metal or polymer layer 224. These vertical planes are in between respective bond pads 210 and respective precision circuitries 204. A BAW resonator die 221 includes the precision circuitry 204. A mold compound 318 physically contacts and covers the various structures of the semiconductor package 302, as shown. The semiconductor package 302 may be coupled to a printed circuit board (PCB) 320, such as by solder joints 322 that physically contact the conductive terminals 310 and metal traces on the PCB 320.

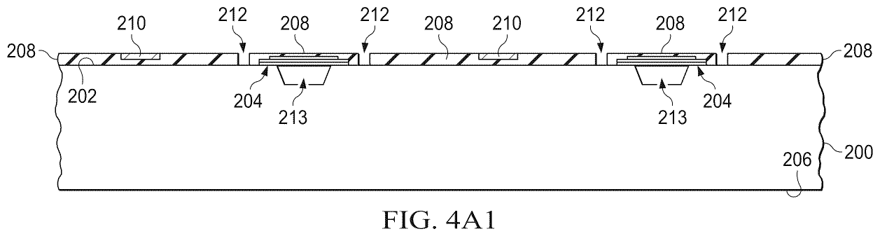

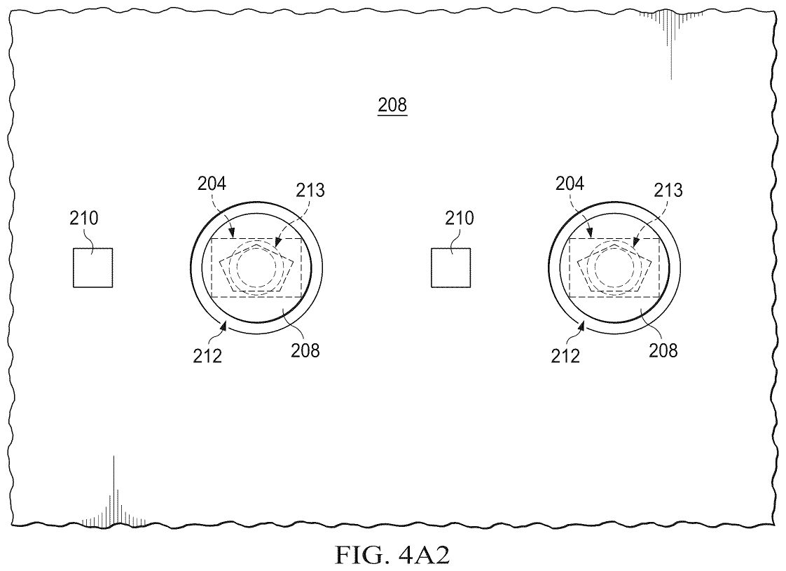

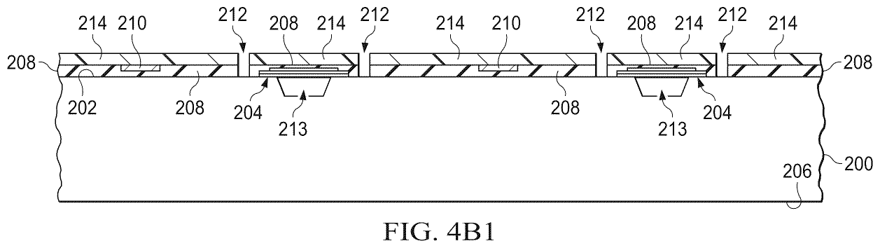

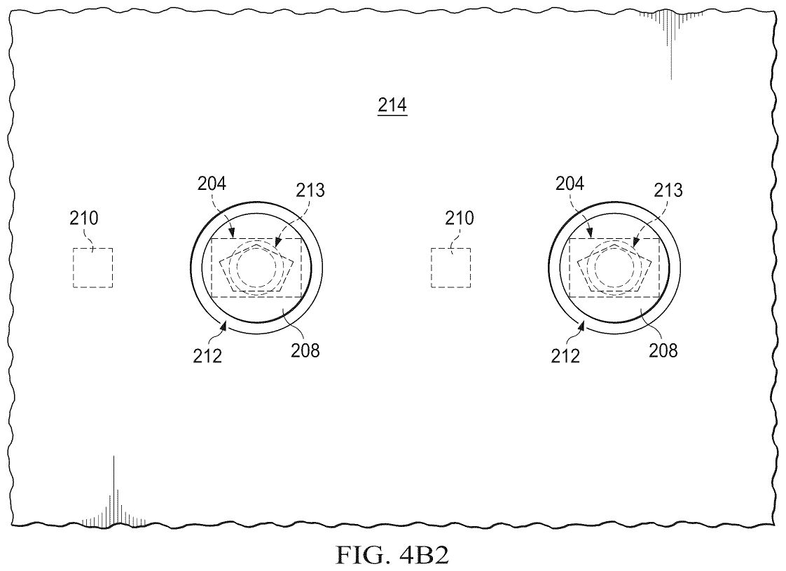

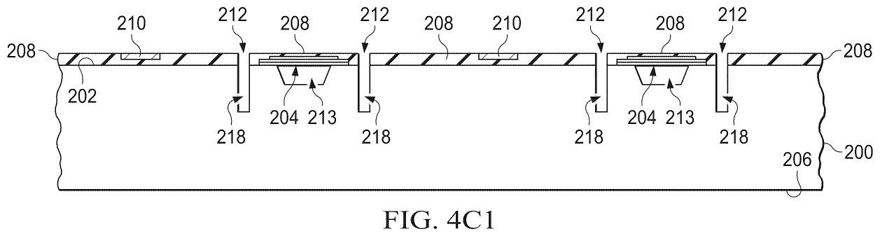

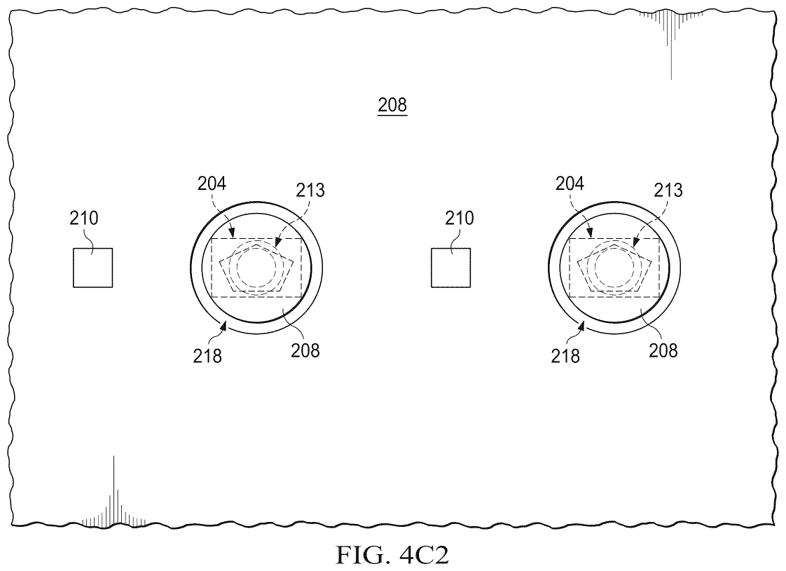

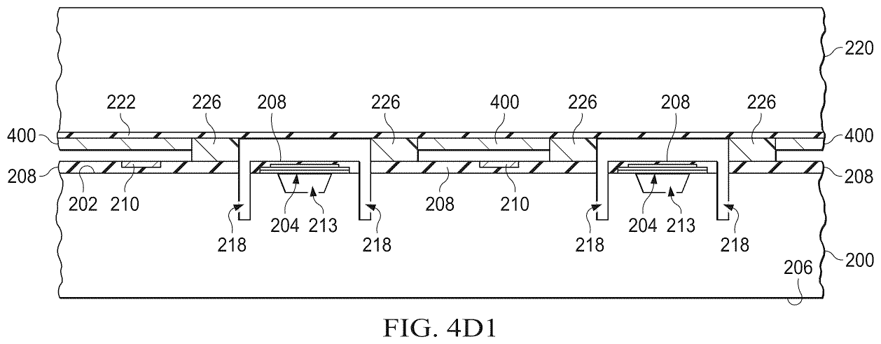

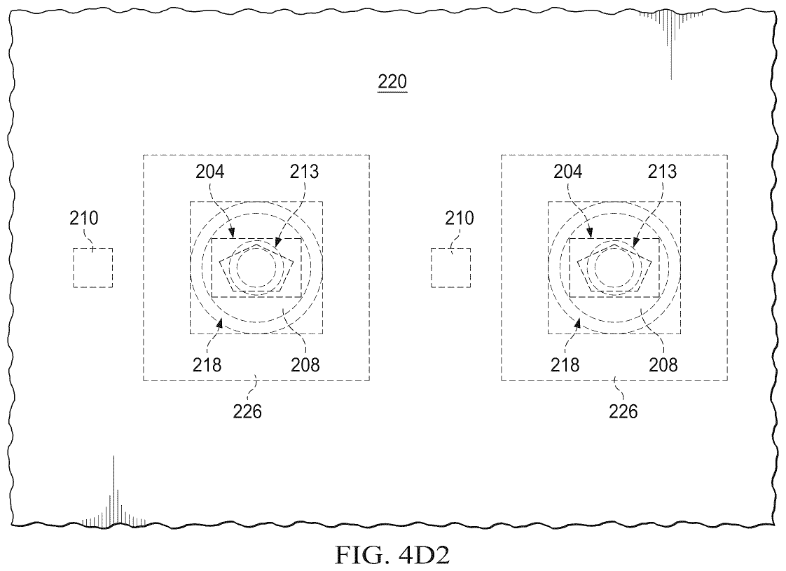

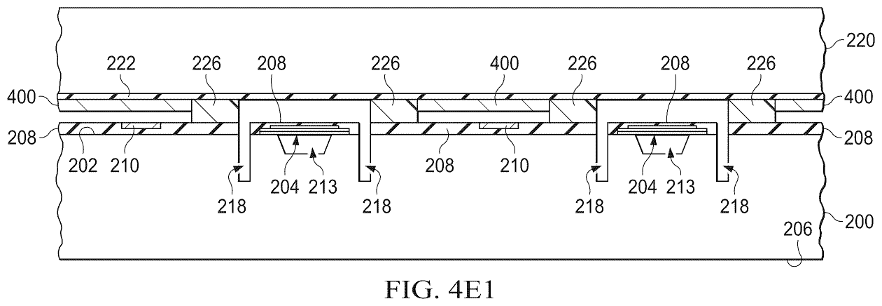

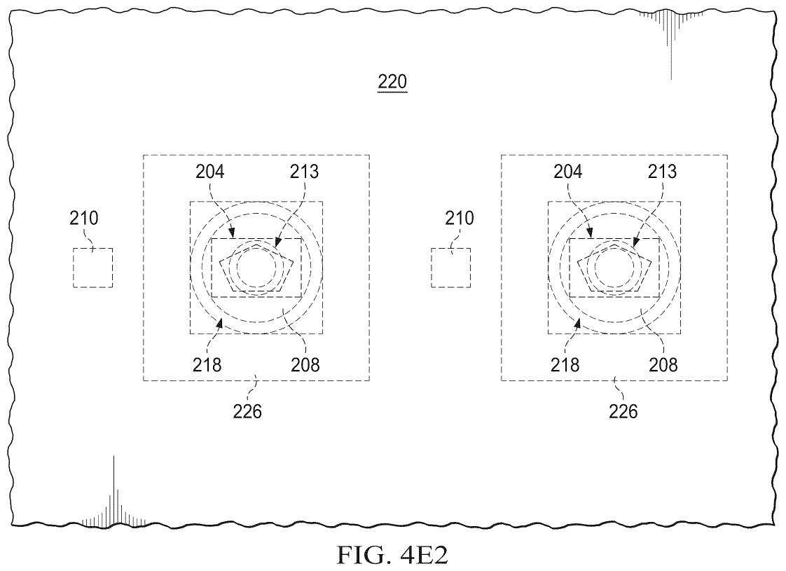

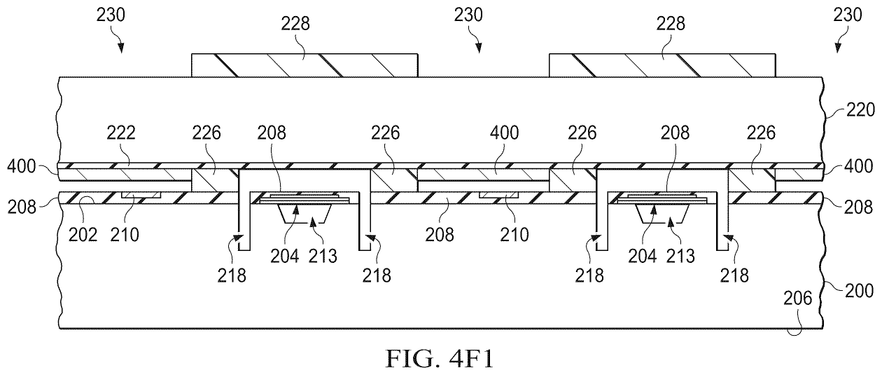

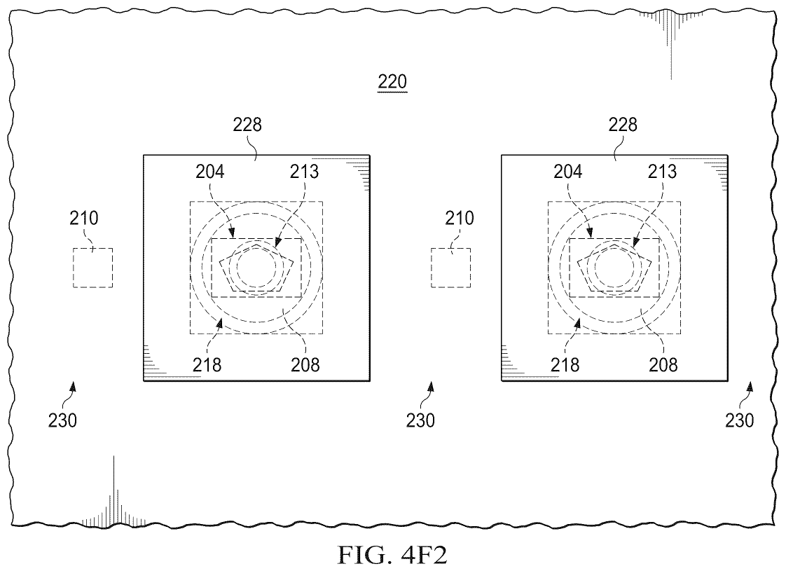

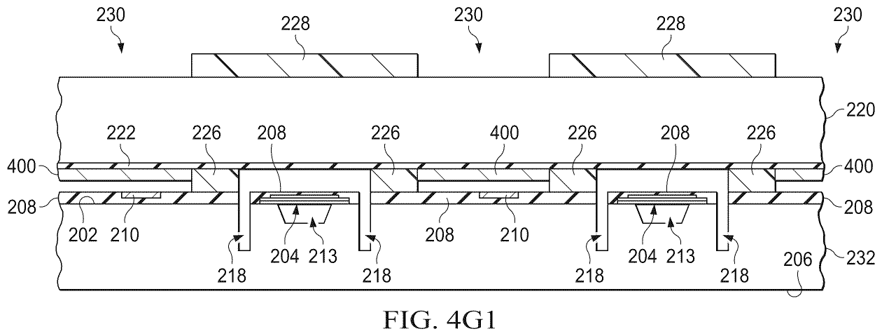

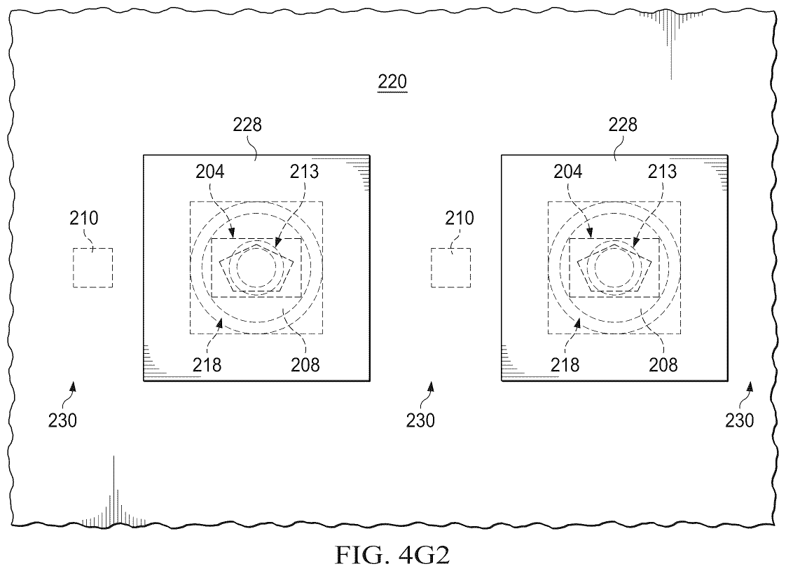

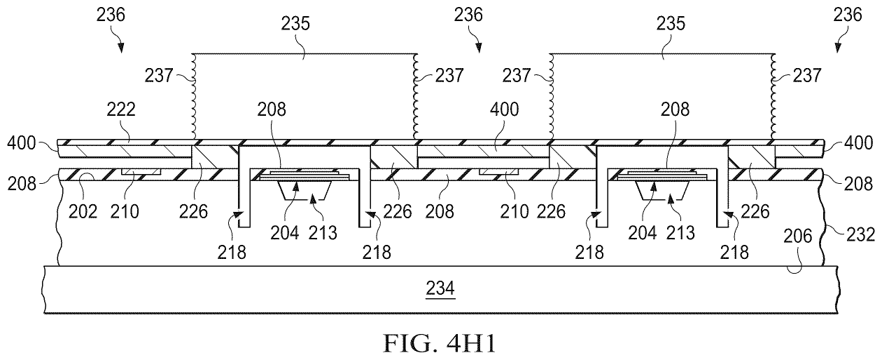

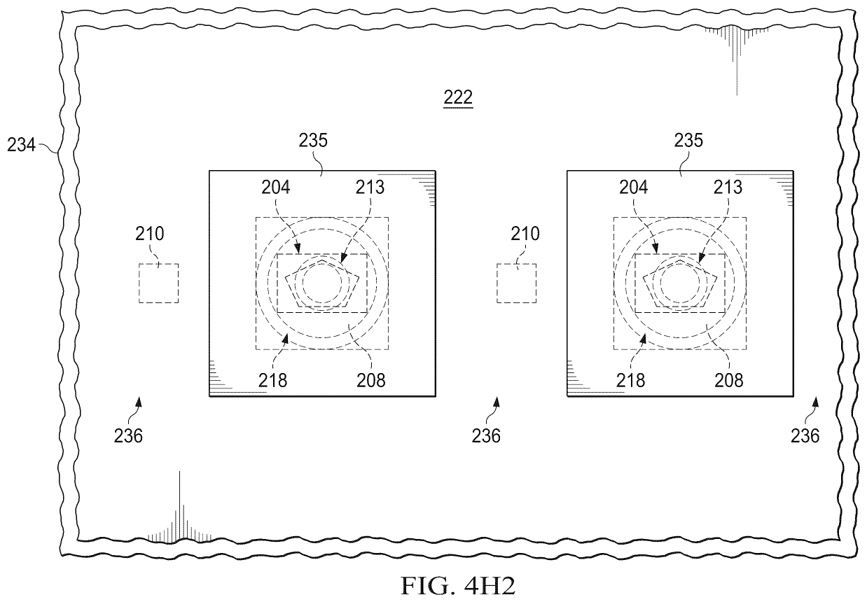

In examples, the metal or polymer layer 224 is a flat sheet that physically contacts all or substantially all of the oxide layer 222. Consequently, portions of the metal or polymer layer 224 and the oxide layer 222 remain in the semiconductor package 302, as shown in FIGS. 3A-3C. However, in other examples, the metal or polymer layer is patterned so that not all of the oxide layer 222 physically contacts the metal or polymer layer. Consequently, the resulting semiconductor package still contains portions of the metal or polymer layer, but not in the same configuration as shown in FIGS. 3A-3C. The manufacture of such examples is now described with simultaneous reference to the method 100 of FIG. 1 and a process flow of FIG. 4A1, 4A2, 4B1, 4B2, 4C1, 4C2, 4D1, 4D2, 4E1, 4E2, 4F1, 4F2, 4G1, 4G2, 4H1, 4H2, 4I1, 4I2, 5A, 5B, and 5C.

The method 100 includes providing a semiconductor wafer having precision circuitry and bond pads on a device side of the wafer (102). FIG. 4A1 and 4A2 depict step 102. Specifically, FIG. 4A1 and 4A2 are profile cross-sectional and top-down views of a structure identical to that of FIG. 2A1 and 2A2. Thus, the description provided above for FIG. 2A1 and 2A2 also applies to FIG. 4A1 and 4A2 and is not repeated here.

The method 100 includes etching trenches circumscribing circuitry in the device side of the semiconductor wafer using a patterned photoresist (104). FIG. 4B1, 4B2, 4C1, and 4C2 depict step 104. Specifically, FIG. 4B1 and 4B2 are profile cross-sectional and top-down views of a structure identical to that of FIG. 2B1 and 2B2. Thus, the description provided above for FIG. 2B1 and 2B2 also applies to FIG. 4B1 and 4B2 and is not repeated here. Similarly, FIG. 4C1 and 4C2 are profile cross-sectional and top-down views of a structure identical to that of FIG. 2C1 and 2C2. Thus, the description provided above for FIG. 2C1 and 2C2 also applies to FIG. 4C1 and 4C2 and is not repeated here.

The method 100 includes coupling a metal or polymer layer having an oxide layer and a semiconductor structure coupled thereto to a support structure on the device side of the semiconductor wafer (106). FIG. 4D1 and 4D2 depict step 106. Specifically, FIG. 4D1 and 4D2 are profile cross-sectional and top-down views of the structure of FIG. 2D1 and 2D2, except that the metal or polymer layer 400 is patterned, unlike the metal or polymer layer 224, which is a flat, continuous sheet. More specifically, the metal or polymer layer 400 is patterned such that the metal or polymer layer 400 is present in the gaps between consecutive instances of the support structures 226. The metal or polymer layer 400 is not present within the spaces circumscribed by the support structures 226. The metal or polymer layer 400 may be patterned such as by a suitable photolithography and/or etching technique, or any other suitable technique, performed prior to the coupling step depicted in FIG. 4D1 and 4D2.

The method 100 includes thinning the semiconductor structure by grinding (108). FIG. 4E1 and 4E2 are profile cross-sectional and top-down views of the structure of FIG. 4D1 and 4D2, except that the semiconductor structure 220 has been thinned by grinding, similar to FIG. 2E1 and 2E2. The description of FIG. 2E1 and 2E2 applies to FIG. 4D1 and 4D2 and thus is not repeated here.

The method 100 includes patterning a photoresist on the semiconductor structure (110). FIG. 4F1 and 4F2 depict step 110. Specifically, FIG. 4F1 and 4F2 are profile cross-sectional and top-down views of a structure identical to that of FIG. 2F1 and 2F2, except that the metal or polymer layer 400 is patterned as described above. The remainder of the description provided above for FIG. 2F1 and 2F2 also applies to FIG. 4F1 and 4F2 and is not repeated here.

The method 100 includes thinning the semiconductor wafer by grinding (112). FIG. 4G1 and 4G2 depict step 112. Specifically, FIG. 4G1 and 4G2 are profile cross-sectional and top-down views of a structure identical to that of FIG. 2G1 and 2G2, except that the metal or polymer layer 400 is patterned as described above. The remainder of the description provided above for FIG. 2G1 and 2G2 also applies to FIG. 4G1 and 4G2 and is not repeated here.

The method 100 includes etching the semiconductor structure using the patterned photoresist to form an opening in the semiconductor structure above the bond pad (114). The method 100 includes stripping the patterned photoresist (116). FIG. 4H1 and 4H2 depict steps 114 and 116. Specifically, FIG. 4H1 and 4H2 are profile cross-sectional and top-down views of a structure identical to that of FIG. 2H1 and 2H2, except that the metal or polymer layer 400 is patterned as described above. The remainder of the description provided above for FIG. 2H1 and 2H2 also applies to FIG. 4H1 and 4H2 and is not repeated here.

The method 100 includes removing portions of the metal or polymer layer and the oxide layer using a water jet (118). FIG. 4I1 and 4I2 depict step 118. Specifically, FIG. 4I1 and 4I2 are profile cross-sectional and top-down views of a structure identical to that of FIG. 2I1 and 2I2, except that the metal or polymer layer 400, which was patterned, is mostly removed from the structure of FIG. 4I1 and 4I2. Small portions of the metal or polymer layer 400 remain, such as denoted by metal or polymer structures 402. The metal or polymer structures 402 extend laterally away from the support structures 226. More specifically, the metal or polymer structures 402 extend away from vertical planes defined by the outer lateral surfaces of the semiconductor structures 235 and the oxide layers 222 in a direction distal to the precision circuitries 204. All of the metal or polymer structures 402 are below the respective oxide layers 222 in a profile and/or cross-sectional view and are within 500 nm of the respective oxide layers 222 in the vertical direction. The metal or polymer structures 402 are irregularly shaped. The metal or polymer structures 402 do not cover (i.e., are not in vertical alignment with) respective precision circuitries 204.

The method 100 includes sawing through the semiconductor wafer to produce a semiconductor die (120), coupling a bond wire to the bond pad (122), and applying a mold compound to the semiconductor die, the semiconductor structure, the bond pad, and the bond wire (124). FIGS. 5A, 5B, and 5C are profile cross-sectional, top-down, and perspective views of the structure of FIG. 4I1 and 4I2, except that the structure of FIG. 4I1 and 4I2 has been singulated (e.g., sawn) to produce singulated structures 500 that are included inside a semiconductor package 502. More specifically, the singulated structure 500 is coupled to a semiconductor die 504 by a die attach layer 506. The semiconductor die 504 includes a device side physically contacting the die attach layer 506, in which circuitry is formed. The semiconductor die 504 includes a non-device side opposite the device side. The semiconductor die 504 includes circuitry in the device side that is configured to operate the circuitry in the singulated structure 500, such as the precision circuitry 204. The semiconductor die 504 includes bond pads 508. The semiconductor die 504 is coupled to conductive terminals 510 by die attach layers 512. The bond pads 210 are coupled to the bond pads 508 by the bond wires 514. Bond wires 516 couple the bond pads 508 to the conductive terminals 510. A BAW resonator die 221 includes the precision circuitry 204. A mold compound 518 physically contacts and covers the various structures of the semiconductor package 502, as shown. The semiconductor package 502 may be coupled to a printed circuit board (PCB) 520, such as by solder joints 522 that physically contact the conductive terminals 510 and metal traces on the PCB 520.

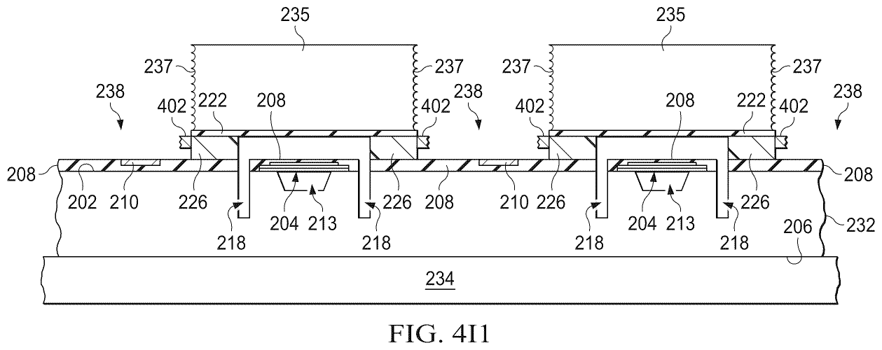

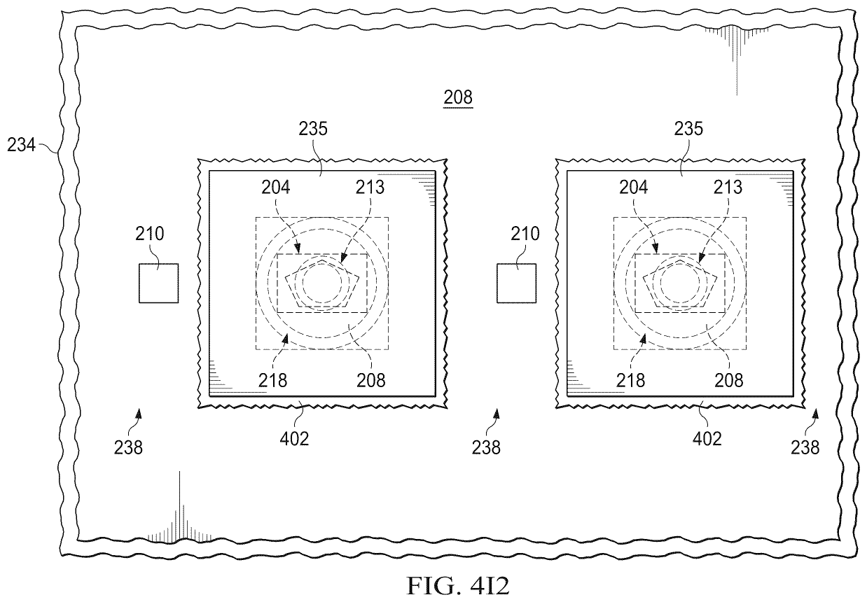

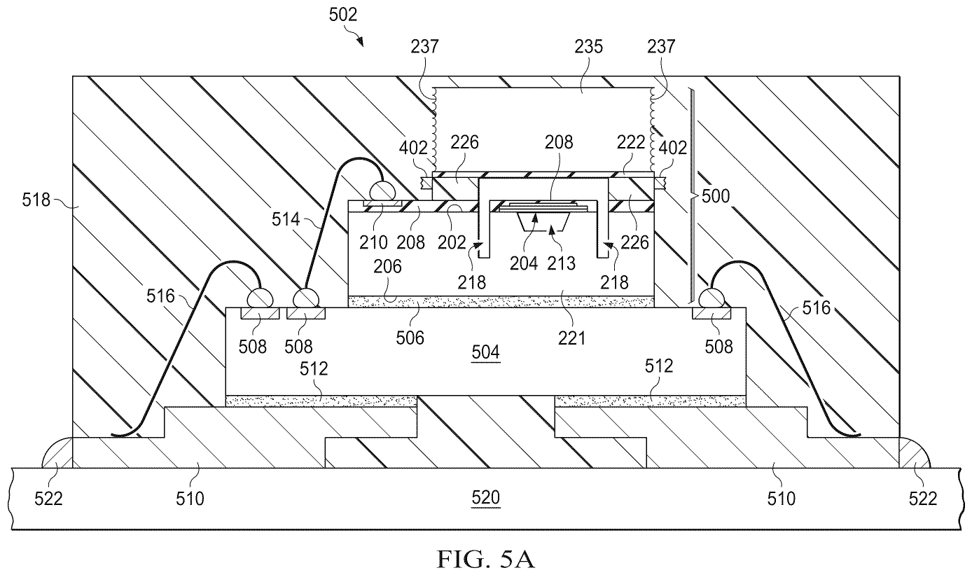

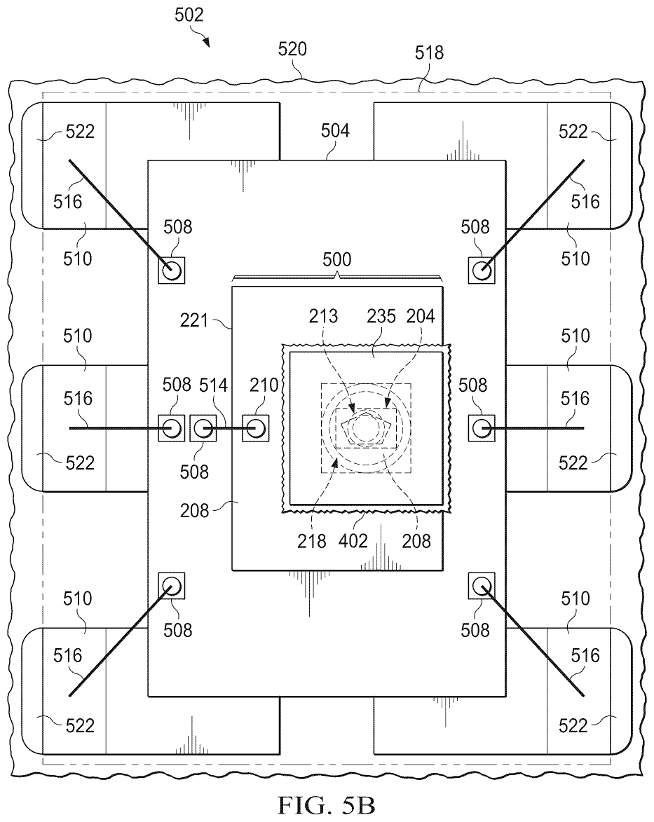

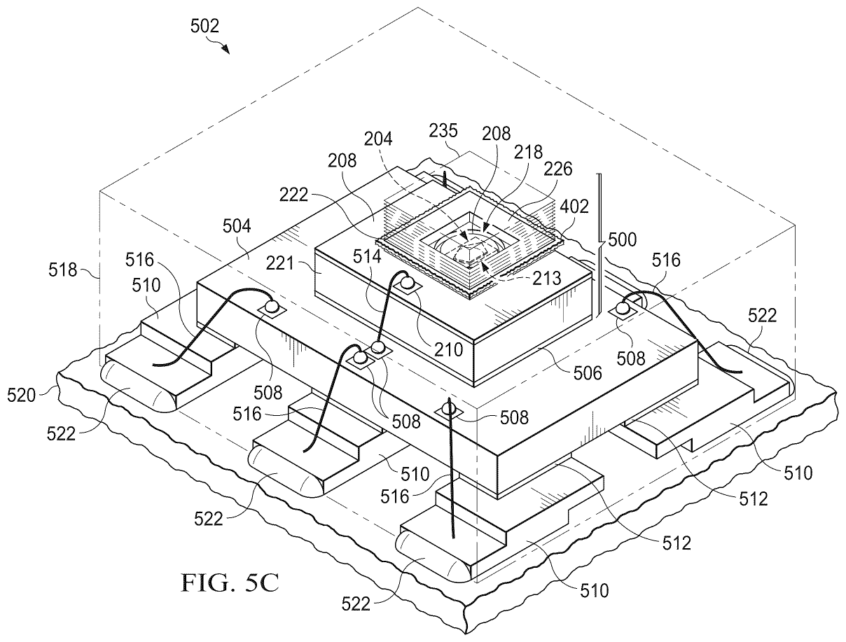

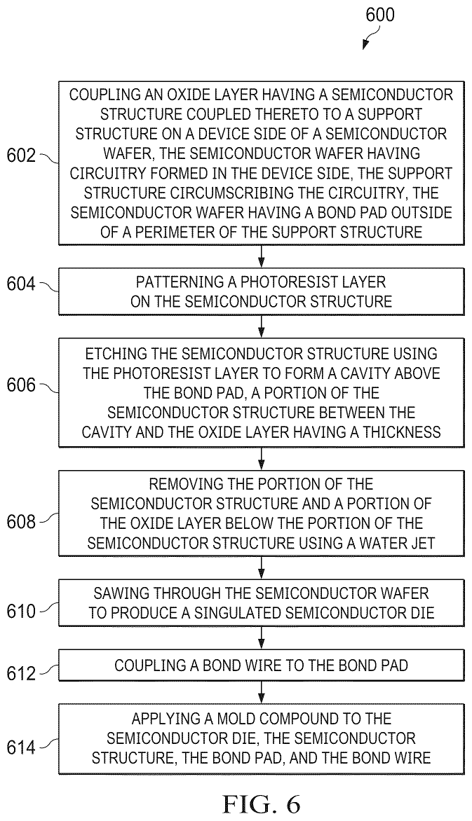

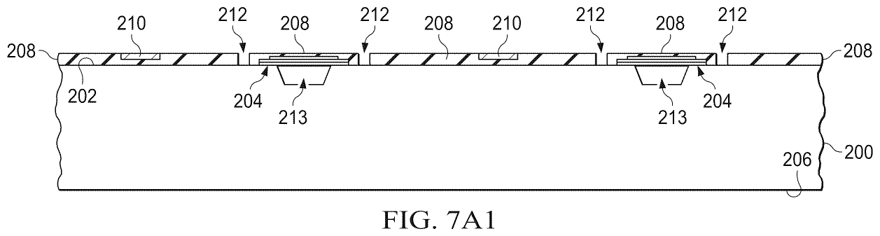

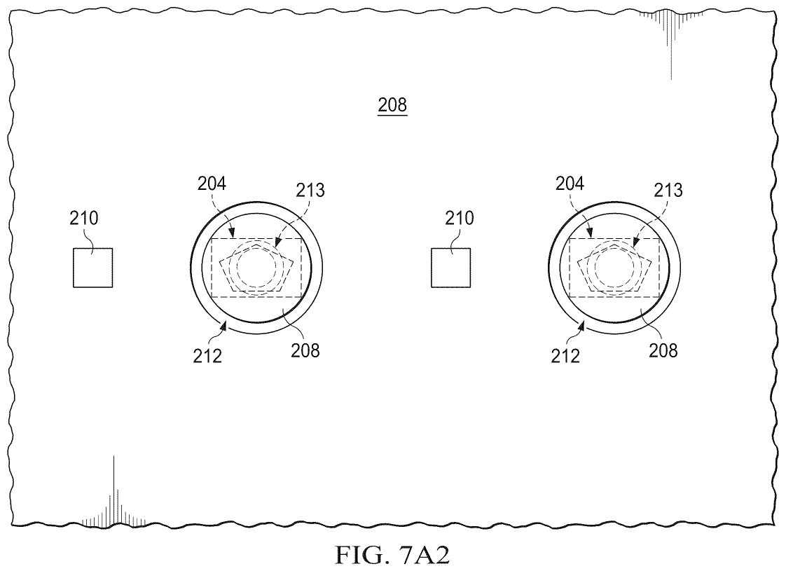

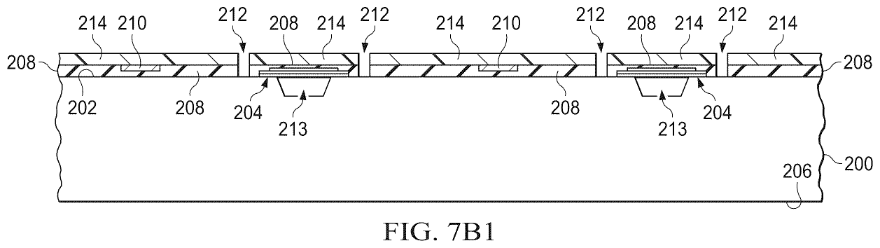

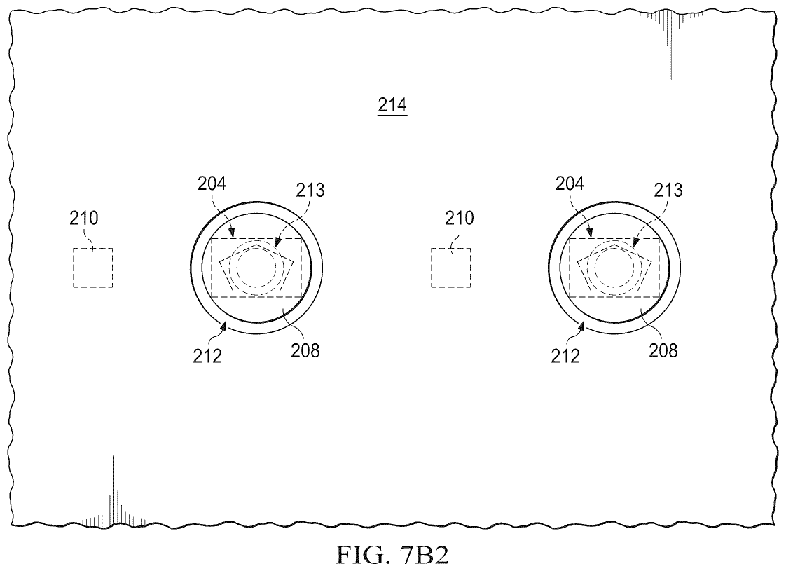

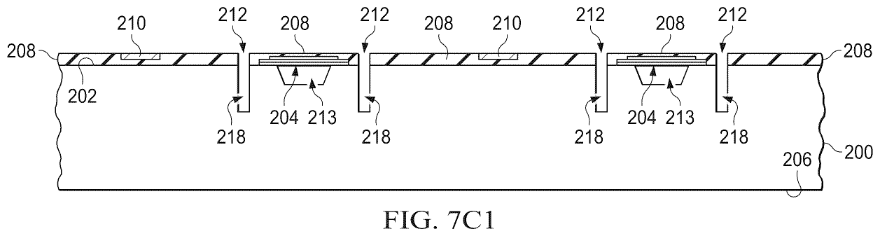

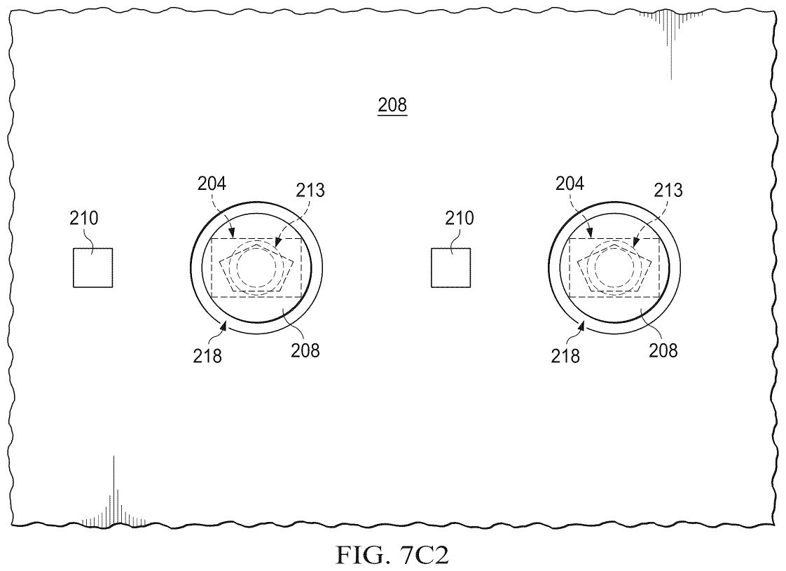

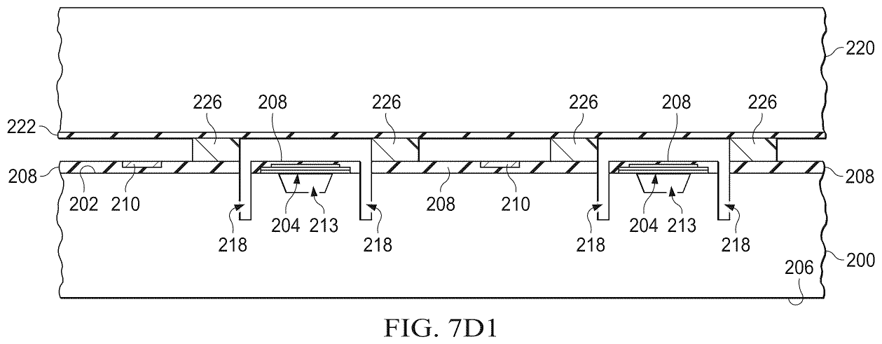

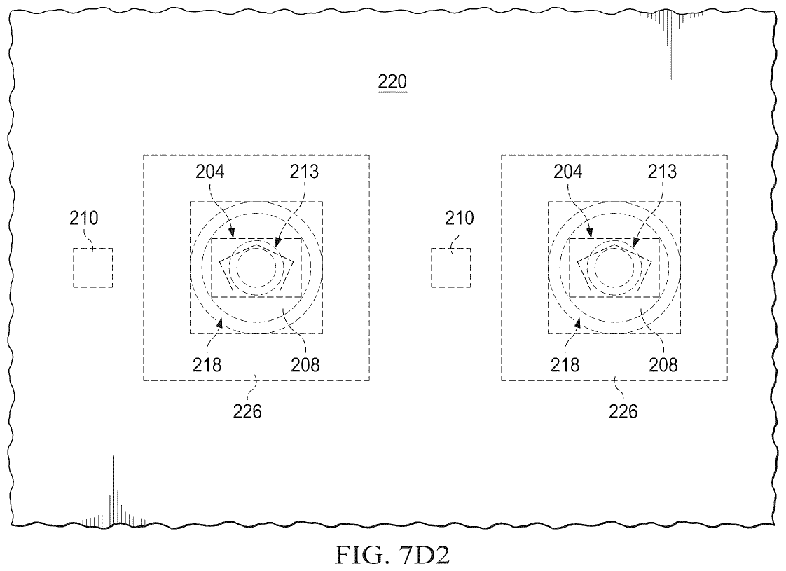

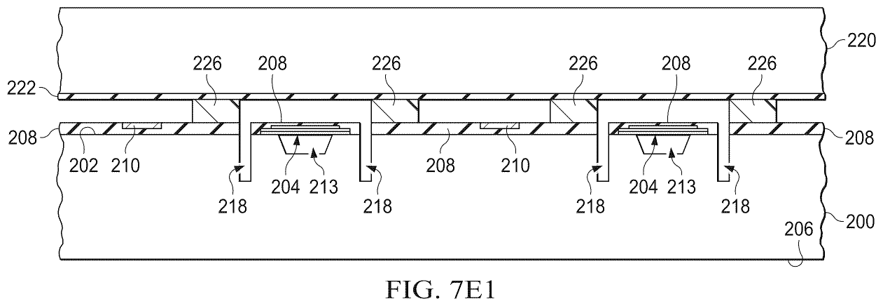

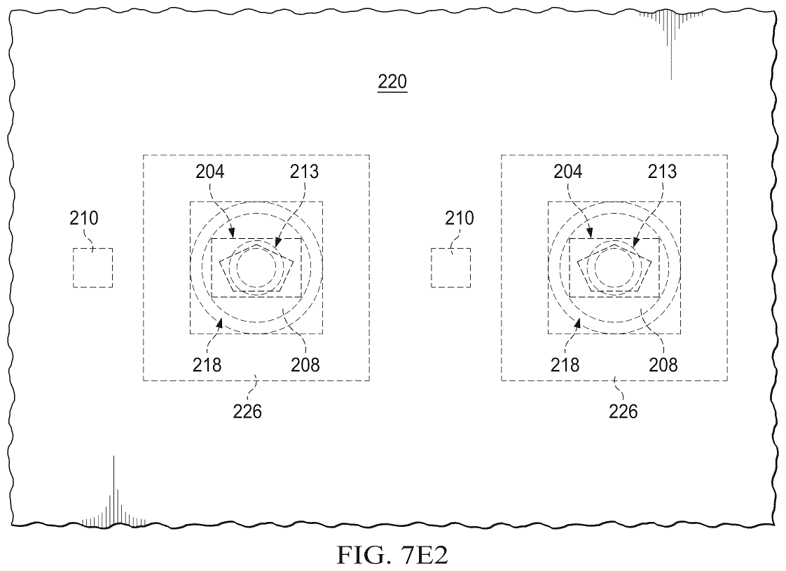

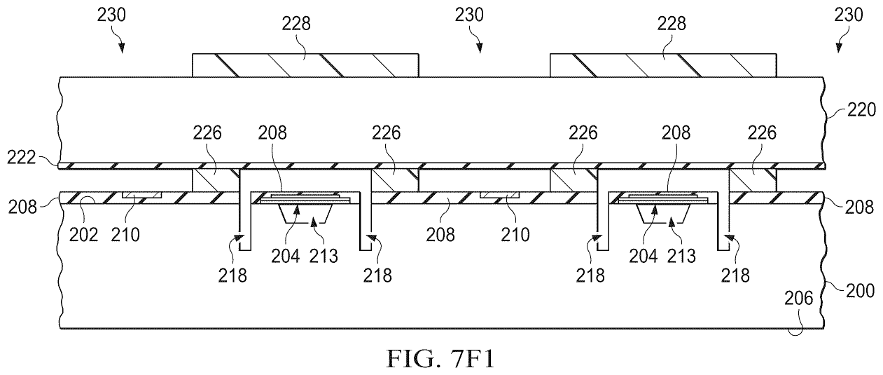

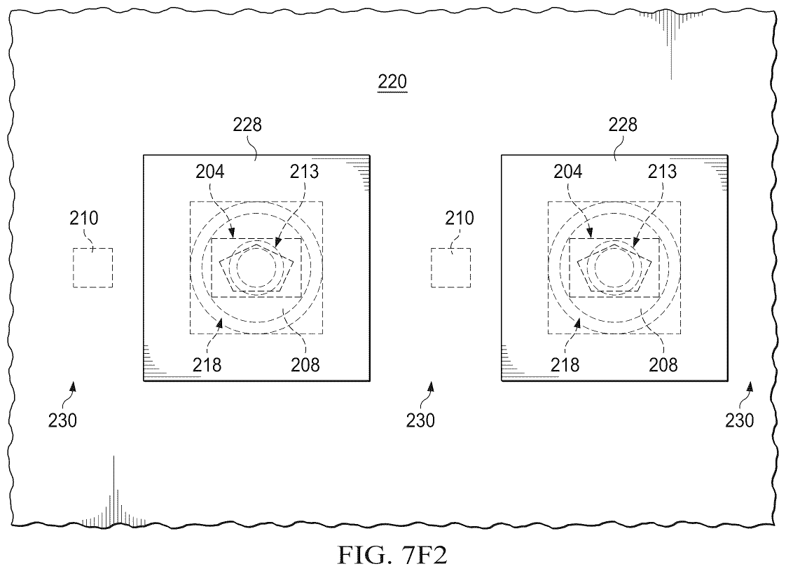

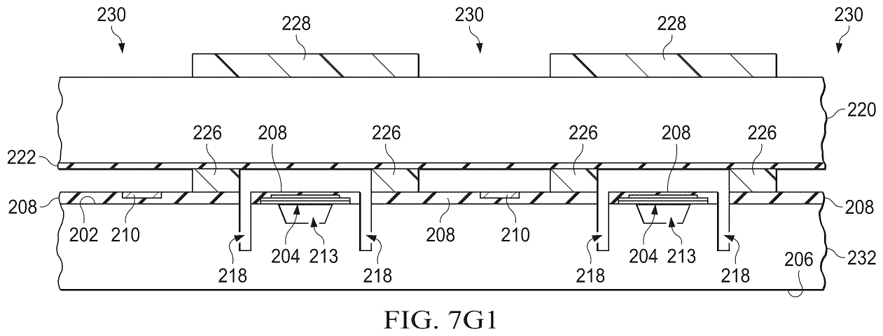

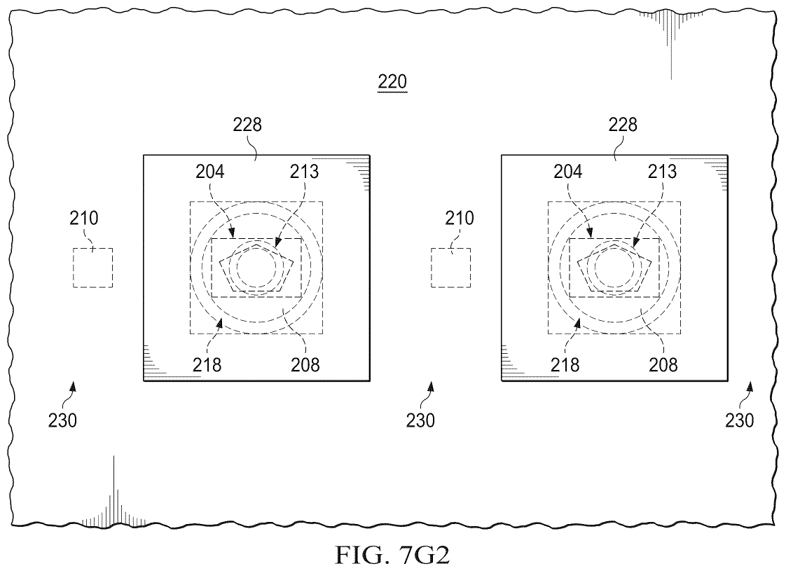

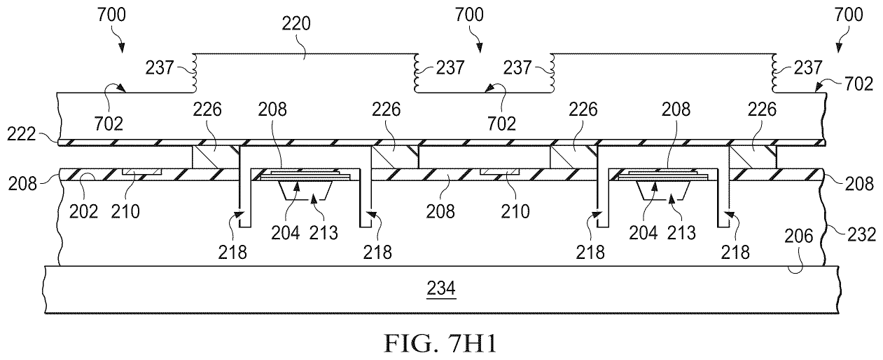

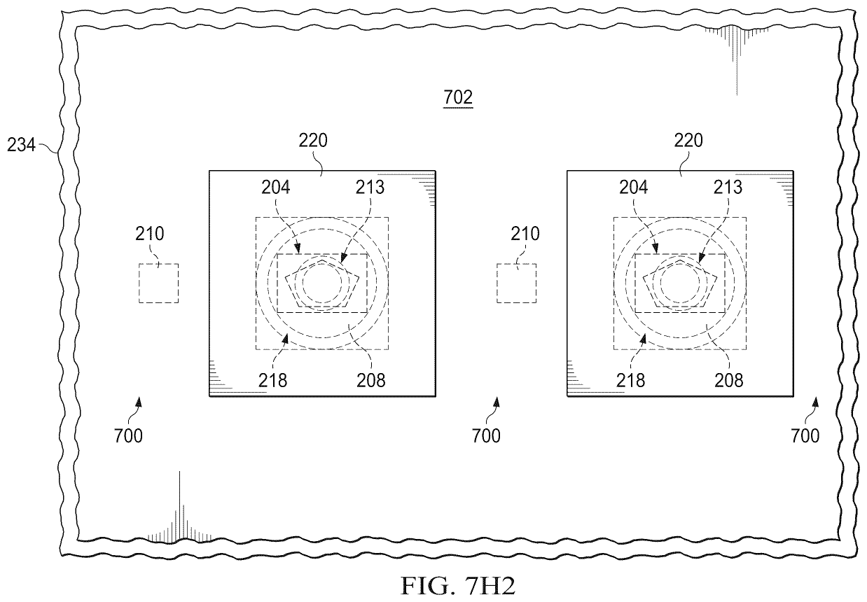

Other semiconductor packages in which the metal or polymer layer is omitted are possible. FIG. 6 is a flow diagram of a method 600 for manufacturing a semiconductor package using a selective etching and water jet technique to protect bond pads from contamination, in accordance with various examples. FIG. 7A1, 7A2, 7B1, 7B2, 7C1, 7C2, 7D1, 7D2, 7E1, 7E2, 7F1, 7F2, 7G1, 7G2, 7H1, 7H2, 7I1, 7I2, 8A, 8B, and 8C are a process flow for a method of manufacturing a semiconductor package using a selective etching and water jet technique to protect bond pads from contamination, in accordance with various examples. Accordingly, FIGS. 6 and 7A1-8C are now described in parallel.

The method 600 includes coupling an oxide layer having a semiconductor structure coupled thereto to a support structure on a device side of a semiconductor wafer, where the semiconductor wafer has circuitry formed in the device side, the support structure circumscribes the circuitry, and the semiconductor wafer has a bond pad outside of a perimeter of the support structure (602). FIG. 7A1 and 7A2 are profile cross-sectional and perspective views of a structure identical to that shown in FIG. 2A1 and 2A2. The description provided above for FIG. 2A1 and 2A2 also applies to the structure in FIG. 7A1 and 7A2 and thus is not repeated here. FIG. 7B1 and 7B2 are profile cross-sectional and perspective views of a structure identical to that shown in FIG. 2B1 and 2B2. The description provided above for FIG. 2B1 and 2B2 also applies to the structure in FIG. 7B1 and 7B2 and thus is not repeated here. FIG. 7C1 and 7C2 are profile cross-sectional and perspective views of a structure identical to that shown in FIG. 2C1 and 2C2. The description provided above for FIG. 2C1 and 2C2 also applies to the structure in FIG. 7C1 and 7C2 and thus is not repeated here. FIG. 7D1 and 7D2 are profile cross-sectional and perspective views of a structure identical to that shown in FIG. 2D1 and 2D2 (and thus the description of FIG. 2D1 and 2D2 provided above also applies to FIG. 7D1 and 7D2), except that the metal or polymer layer 224 is omitted. Thus, the oxide layer 222 physically contacts the support structures 226. FIG. 7E1 and 7E2 are profile cross-sectional and top-down views of the structure of FIG. 7D1 and 7D2, except that the semiconductor structure 220 has been thinned by grinding, in the manner described above.

The method 600 includes patterning a photoresist layer on the semiconductor structure (604). FIG. 7F1 and 7F2 are profile cross-sectional and top-down views of a structure that is identical to that shown in FIG. 2F1 and 2F2, except that the metal or polymer layer 224 is omitted. The description of FIG. 2F1 and 2F2 otherwise applies to FIG. 7F1 and 7F2. Further, FIG. 7G1 and 7G2 are profile cross-sectional and top-down views of a structure that is identical to that shown in FIG. 2G1 and 2G2, except that the metal or polymer layer 224 is omitted. The description of FIG. 2G1 and 2G2 otherwise applies to FIG. 7G1 and 7G2.

The method 600 includes etching the semiconductor structure using the photoresist layer to form a cavity above the bond pad (606). A portion of the semiconductor structure between the cavity and the oxide layer has a thickness (606). FIG. 7H1 and 7H2 are profile cross-sectional and top-down views of the structure of FIG. 7G1 and 7G2, except that an etching (e.g., plasma etching) process has been performed into the semiconductor structure 220 using the openings 230 in the patterned photoresist 228 to create openings 700. The etching is performed sufficiently deep such that portions 702 of the semiconductor structure 220 remain in between the bottoms of the openings 700 and the oxide layer 222. The walls of the openings 700 include striations 237, similar to those described above. The above description of the striations 237 also applies to the striations 237 formed in FIG. 7H1 and 7H2. Each of the portions 702 has a thickness ranging from 200 nm to 500 nm, with a thickness below this range being disadvantageous because of the risk of over-etching and damaging or breaking through the oxide layer, and with a thickness above this range being disadvantageous because of the risk that the portions 702 will not be fully removed during subsequent manufacturing processes.

The method 600 includes removing the portion of the semiconductor structure and a portion of the oxide layer below the portion of the semiconductor structure using a water jet (608). FIG. 7I1 and 7I2 are profile cross-sectional and top-down views of the structure of FIG. 7H1 and 7H2, except that the portions 702 and the portions of the oxide layer 222 physically contacting those portions 702 are removed by a water jet process, thereby resulting in singulated semiconductor structures 235. Consequently, each semiconductor structure 235 has four lateral surfaces that are partially, but not fully, covered in striations 237. The striations 237 are absent from the portions of the four lateral surfaces that were previously physically contacting the portions 702 prior to the removal of the portions 702 (i.e., the vertical thickness of the non-striated areas of the four lateral surfaces range between 200 nm and 500 nm, as this is the acceptable thickness range for the portions 702 prior to removal). The oxide layer 222 is not striated.

The method 600 includes sawing through the semiconductor wafer to produce a singulated semiconductor die (610), coupling a bond wire to the bond pad (612), and applying a mold compound to the semiconductor die, the semiconductor structure, the bond pad, and the bond wire (614). FIGS. 8A-8C are profile cross-sectional, top-down, and perspective views of the structure of FIG. 7I1 and 7I2 incorporated into a semiconductor package 502. Semiconductor package 802 of FIGS. 8A-8C is identical to semiconductor package 502 of FIGS. 5A-5C, except that the metal or polymer structures 402 are omitted, and the locations of the striations 237 are different, as described above. The semiconductor packages 502 of FIGS. 5A-5C and 8A-8C are otherwise identical, and thus the description of FIGS. 5A-5C also applies to FIGS. 8A-8C (with the exceptions described above), and thus is not repeated here.

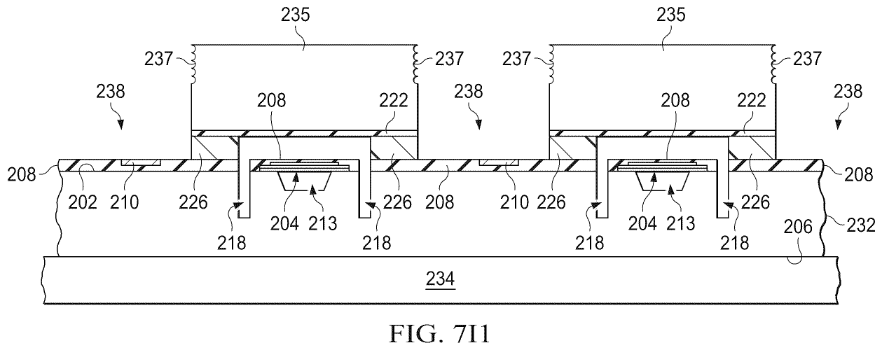

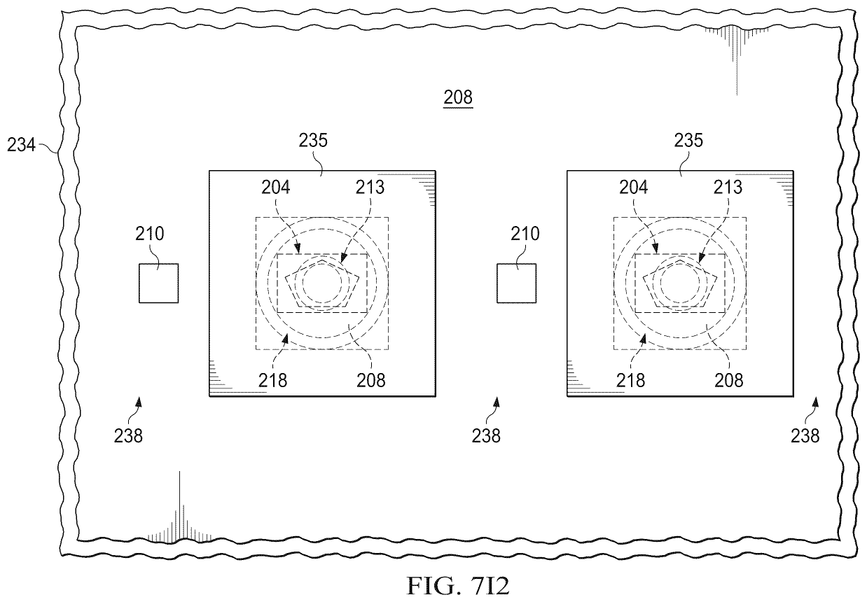

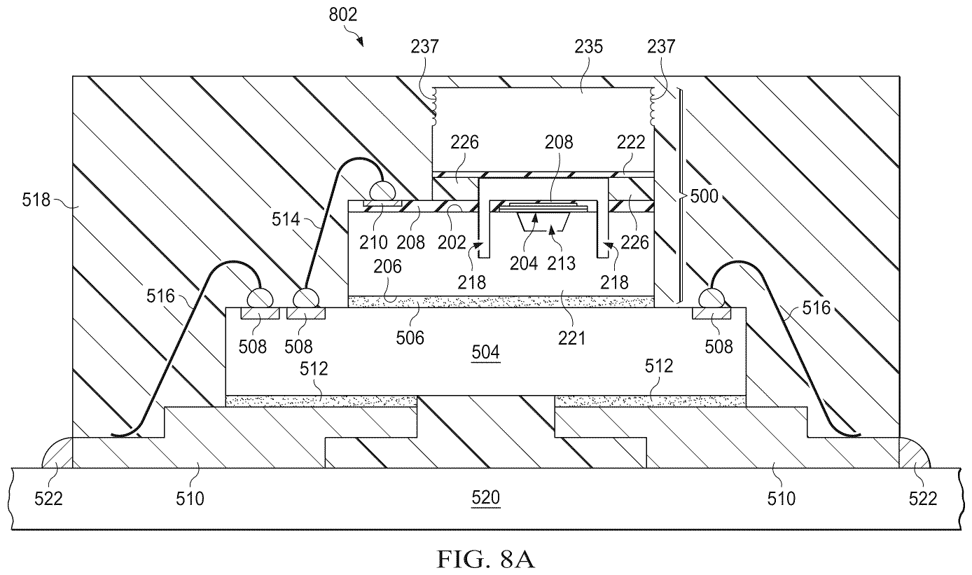

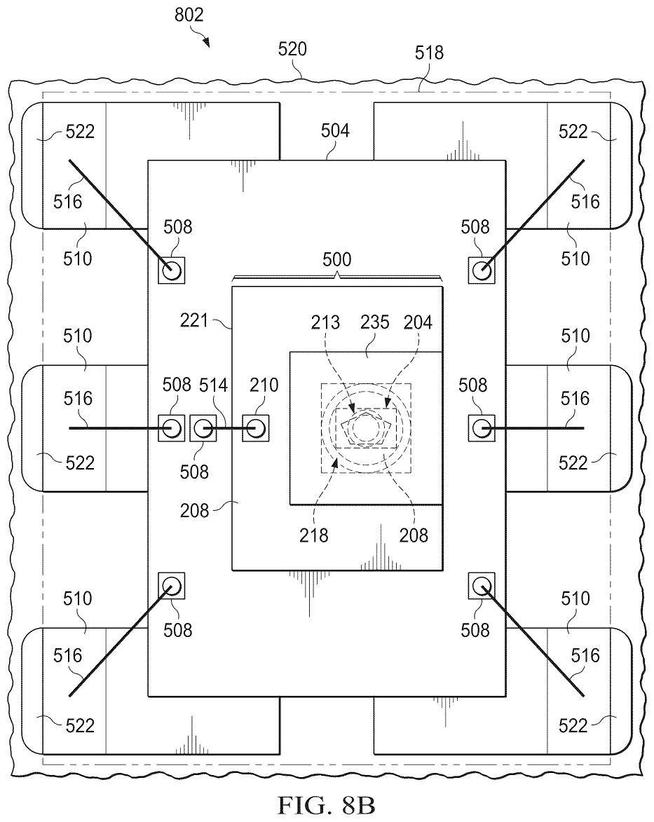

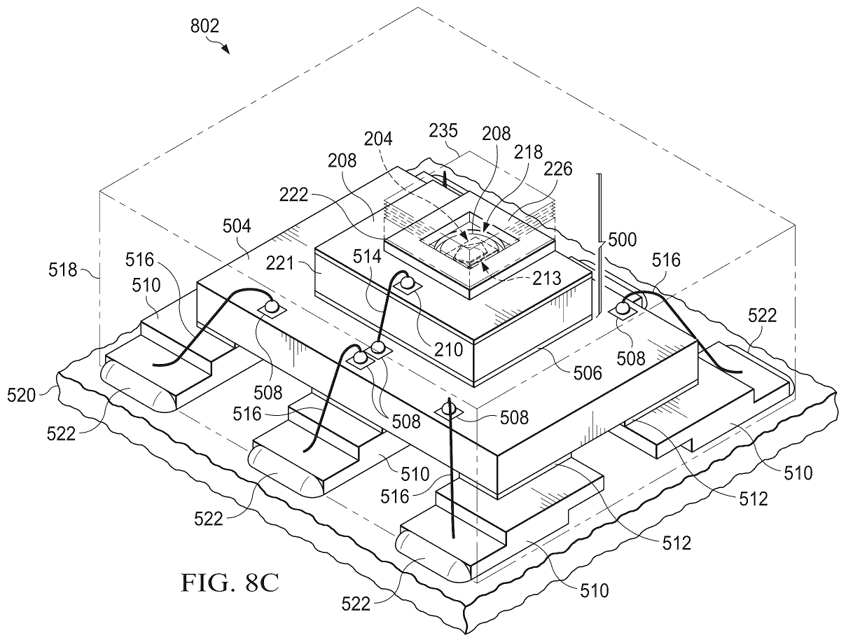

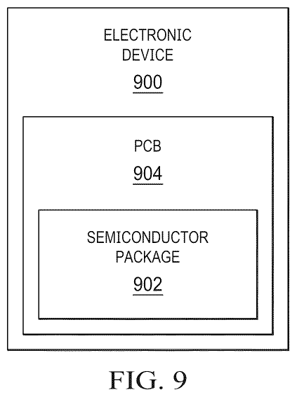

FIG. 9 is a block diagram of an example electronic device 900 including a semiconductor package 902 coupled to a PCB 904. The semiconductor package 902 is manufactured according to any of the techniques described herein. For example, the semiconductor package 902 is representative of the semiconductor packages 302 and 502, described above.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” “conductive terminal,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a bulk acoustic wave (BAW) resonator die having a device side in which circuitry is formed;
a support structure coupled to the device side and circumscribing the circuitry;
a bond pad coupled to the device side and outside a perimeter of the support structure;
a metal or polymer layer coupled to the support structure and covering the circuitry;
an etch stop layer coupled to the metal or polymer layer; and
a passive semiconductor structure coupled to the etch stop layer such that the etch stop layer is between the semiconductor structure and the metal or polymer layer, wherein outer lateral surfaces of the metal or polymer layer, the etch stop layer, and the semiconductor structure are approximately flush with each other, an entirety of the outer lateral surfaces of the semiconductor structure having plasma-etch striations.

2. The semiconductor package of claim 1, wherein the metal or polymer layer has a thickness between 0.5 microns to 5 microns.

3. The semiconductor package of claim 1, wherein the metal or polymer layer is selected from the group consisting of aluminum, copper, tungsten, and titanium-tungsten.

4. The semiconductor package of claim 1, wherein the metal or polymer layer is selected from the group consisting of polyimide, benzocyclobutene, polydimethylsiloxane, SU-8, and polybenzoxazoles.

5. The semiconductor package of claim 1, wherein the BAW resonator die includes a trench circumscribing the circuitry, and wherein the support structure circumscribes the trench.

6. The semiconductor package of claim 1, wherein the etch stop layer has a thickness ranging from 0.1 microns to 3 microns.

7. A semiconductor package, comprising:
a bulk acoustic wave (BAW) resonator die having a device side in which circuitry is formed;
a support structure coupled to the device side and circumscribing the circuitry;
a bond pad coupled to the device side and outside a perimeter of the support structure;
an oxide layer coupled to the support structure;
a passive semiconductor structure coupled to the oxide layer such that the oxide layer is between the semiconductor structure and the support structure, wherein outer lateral surfaces of the oxide layer and the semiconductor structure are approximately flush with each other, an entirety of the outer lateral surfaces of the semiconductor structure having striations; and
a metal or polymer structure physically contacting at least one of the outer lateral surfaces of the semiconductor structure, the metal or polymer structure extending away from a vertical plane defined by the outer lateral surfaces of the semiconductor structure and the oxide layer in a direction distal to the circuitry.

8. The semiconductor package of claim 7, wherein all of the metal or polymer structure is within 500 nm of the oxide layer in the vertical direction.

9. The semiconductor package of claim 8, wherein the metal or polymer structure is below the oxide layer when viewed in a profile view.

10. The semiconductor package of claim 7, wherein the metal or polymer structure is selected from the group consisting of aluminum, copper, tungsten, and titanium-tungsten.

11. The semiconductor package of claim 7, wherein the metal or polymer structure is selected from the group consisting of polyimide, benzocyclobutene, polydimethylsiloxane, SU-8, and polybenzoxazoles.

12. The semiconductor package of claim 7, wherein the metal or polymer structure does not cover the circuitry.

13. The semiconductor package of claim 7, wherein the metal or polymer structure is irregularly shaped.

14. The semiconductor package of claim 7, wherein the BAW resonator die includes a trench circumscribing the circuitry, and wherein the support structure circumscribes the trench.

15. The semiconductor package of claim 7, wherein the oxide layer has a thickness ranging from 0.1 microns to 3 microns.

16. A semiconductor package, comprising:
a bulk acoustic wave (BAW) resonator die having a device side in which circuitry is formed;
a support structure coupled to the device side and circumscribing the circuitry;
a bond pad coupled to the device side and outside a perimeter of the support structure;
an oxide layer physically contacting the support structure and covering the circuitry, the support structure separating the oxide layer from the BAW resonator die by a gap, the oxide layer having a first outer lateral surface;
a passive semiconductor structure physically contacting the oxide layer and covering the circuitry, the semiconductor structure having a second outer lateral surface sharing a vertical plane with the first outer lateral surface and having top and bottom surfaces;
a bond wire coupled to the bond pad and to a conductive terminal; and
a mold compound covering the BAW resonator die, the support structure, the bond pad, the oxide layer, the semiconductor structure, and the bond wire, the conductive terminal exposed on an external surface of the mold compound,
wherein a first portion of the second outer lateral surface extending from the top surface of the semiconductor structure to a level between the top and bottom surfaces of the semiconductor structure includes striations, wherein a second portion of the second outer lateral surface extending from the level to the bottom surface of the semiconductor structure lacks striations, and wherein the first outer lateral surface lacks striations.

17. The semiconductor package of claim 16, wherein the striations are plasma-etch striations.

18. The semiconductor package of claim 16, wherein the bond pad is farther from the circuitry than is the vertical plane.

19. The semiconductor package of claim 16, further comprising a trench circumscribing the circuitry, and wherein the support structure circumscribes the trench.

20. The semiconductor package of claim 16, wherein the level is between 200 nm and 500 nm from the bottom surface of the semiconductor structure.

21. The semiconductor package of claim 16, wherein at least one of the striations extends across four outer lateral surfaces of the semiconductor structure.

22. A method for manufacturing a semiconductor package, comprising:
coupling an oxide layer having a semiconductor structure coupled thereto to a support structure on a device side of a semiconductor wafer, the semiconductor wafer having circuitry formed in the device side, the support structure circumscribing the circuitry, the semiconductor wafer having a bond pad outside of a perimeter of the support structure;
patterning a photoresist layer on the semiconductor structure;
etching the semiconductor structure using the photoresist layer to form a cavity above the bond pad, a portion of the semiconductor structure between the cavity and the oxide layer having a thickness;
removing the portion of the semiconductor structure and a portion of the oxide layer below the portion of the semiconductor structure using a water jet;
sawing through the semiconductor wafer to produce a singulated semiconductor die;
coupling a bond wire to the bond pad; and
applying a mold compound to the semiconductor die, the semiconductor structure, the bond pad, and the bond wire.

23. The method of claim 22, wherein the thickness ranges from 200 nm to 500 nm.
